(19) United States
(12) Patent Application Publication
(10) Pub. No.: US 2024/0357878 A1
(43) Pub. Date: Oct. 24, 2024

(54) DISPLAY SUBSTRATE AND DISPLAY DEVICE

(71) Applicants: Chengdu BOE Optoelectronics Technology Co., Ltd., Chengdu(Sichuan) (CN); BOE TECHNOLOGY GROUP CO., LTD., Beijing (CN)

(72) Inventors: Hui LU, Beijing (CN); Zhenglong YAN, Beijing (CN); Yanyang SHANG, Beijing (CN); Ling SHI, Beijing (CN); Ming YANG, Beijing (CN)

(73) Assignees: Chengdu BOE Optoelectronics Technology Co., Ltd., Chengdu (Sichuan) (CN); BOE TECHNOLOGY GROUP CO., LTD., Beijing (CN)

(21) Appl. No.: 18/039,306

(22) PCT Filed: May 31, 2022
(86) PCT No.: PCT/CN2022/096120

§ 371 Date: May 30, 2023

(51) Int. Cl. H10K 59/131; H10K 59/122; H10K 59/126; H10K 59/35

(52) U.S. Cl. CPC H10K 59/131; H10K 59/122; H10K 59/126; H10K 59/35

(57) ABSTRACT

The disclosure provides a display substrate and a display device. The display substrate has a plurality of sub-pixels, and includes a base substrate, a light-shielding layer, a pixel driving circuit layer, and a pixel definition layer. The light-shielding layer is disposed on the base substrate, and includes a plurality of first light transmission openings. The pixel driving circuit layer is disposed on the light-shielding layer. The pixel definition layer is disposed on the pixel driving circuit layer, and includes a plurality of sub-pixel openings, each sub-pixel includes a pixel driving circuit disposed in the pixel driving circuit layer and a light-emitting device at least partially disposed in the sub-pixel opening, and orthographic projections of the first light transmission openings on the base substrate are respectively located between orthographic projections of adjacent sub-pixel openings on the base substrate.

### TECHNICAL FIELD

At least one embodiment of the present disclosure relates to a display substrate and a display device.

### BACKGROUND

Organic Light Emitting Diode (OLED) display devices have a series of advantages such as self-illumination, high contrast, high definition, wide viewing angle, low power consumption, fast response speed, and low manufacturing cost, and the OLED display devices have become one of the key development directions of a new generation of display devices, thus receive more and more attention.

### SUMMARY

At least one embodiment of the present disclosure provides a display substrate. The display substrate has a plurality of sub-pixels, and includes a base substrate, a light-shielding layer, a pixel driving circuit layer, and a pixel definition layer. The light-shielding layer is disposed on the base substrate, and includes a plurality of first light transmission openings. The pixel driving circuit layer is disposed on a side of the light-shielding layer away from the base substrate. The pixel definition layer is disposed on a side of the pixel driving circuit layer away from the base substrate, and includes a plurality of sub-pixel openings, wherein each of the plurality of sub-pixels includes a pixel driving circuit disposed in the pixel driving circuit layer and a light-emitting device at least partially disposed in one of the plurality of sub-pixel openings, and orthographic projections of the plurality of first light transmission openings on the base substrate are respectively located between orthographic projections of adjacent sub-pixel openings of the plurality of sub-pixel openings on the base substrate.

For example, the display substrate provided by at least one embodiment of the present disclosure further includes a black matrix layer disposed on a side of the light-emitting device away from the base substrate, wherein the black matrix layer includes a plurality of second light transmission openings and a plurality of third light transmission openings, orthographic projections of the plurality of sub-pixel openings on the base substrate are respectively at least partially overlapped with orthographic projections of the plurality of second light transmission openings on the base substrate; the plurality of third light transmission openings are respectively disposed between adjacent second light transmission openings of the plurality of second light transmission openings; and orthographic projections of at least part of the plurality of first light transmission openings on the base substrate are respectively at least partially overlapped with orthographic projections of the plurality of third light transmission openings on the base substrate.

For example, in the display substrate provided by at least one embodiment of the present disclosure, the orthographic projections of the at least part of the plurality of first light transmission openings on the base substrate are respectively located within the orthographic projections of the plurality of third light transmission openings on the base substrate.

For example, in the display substrate provided by at least one embodiment of the present disclosure, distances between boundaries of the orthographic projections of the at least part of the plurality of first light transmission openings on the base substrate and boundaries of the orthographic projections of the plurality of third light transmission openings on the base substrate are from 0.5 micron to 1.5 micron.

For example, in the display substrate provided by at least one embodiment of the present disclosure, the pixel driving circuit layer includes first signal lines and second signal lines disposed parallel to each other and periodically arranged, the first signal lines and the second signal lines are configured to provide different electrical signals to the plurality of sub-pixels, the orthographic projections of the plurality of first light transmission openings on the base substrate are respectively located between an orthographic projection of one of the first signal lines on the base substrate and an orthographic projection of one of the second signal lines closest to the one of the first signal lines on the base substrate.

For example, in the display substrate provided by at least one embodiment of the present disclosure, the first signal lines are light-emitting control signal lines, and the second signal lines are reset control lines.

For example, in the display substrate provided by at least one embodiment of the present disclosure, the plurality of sub-pixels include a first row of sub-pixels and a second row of sub-pixels adjacent to the first row of sub-pixels and located at a next tier of the first row of sub-pixels, the pixel driving circuits of the first row of sub-pixels share one light-emitting control signal line of the light-emitting control signal lines and one reset control line of the reset control lines, the pixel driving circuits of the second row of sub-pixels share one light-emitting control signal line of the light-emitting control signal lines and one reset control line of the reset control lines, wherein between an orthographic projection of the one light-emitting control signal line shared by the pixel driving circuits of the first row of sub-pixels on the base substrate and an orthographic projection of the one reset control line shared by the pixel driving circuits of the second row of sub-pixels on the base substrate, orthographic projections of a row of first light transmission openings on the base substrate are included.

For example, in the display substrate provided by at least one embodiment of the present disclosure, the driving circuit layer includes third signal lines disposed in parallel and arranged periodically, the third signal lines intersect the first signal lines and the second signal lines respectively, the third signal lines are configured to provide power supply signals to the plurality of sub-pixels, and the third signal lines include hollow parts, and the orthographic projections of the first light transmission openings on the base substrate are located within orthographic projections of the hollow parts on the base substrate.

For example, in the display substrate provided by at least one embodiment of the present disclosure, orthographic projections of the third light transmission openings on the base substrate are not overlapped with orthographic projections of the first signal lines and orthographic projections of the second signal lines on the base substrate, and the orthographic projections of the third light transmission openings on the base substrate are located within the orthographic projections of the hollow parts on the base substrate.

For example, in the display substrate provided by at least one embodiment of the present disclosure, the plurality of sub-pixels include first sub-pixels, second sub-pixels and third sub-pixels, the black matrix layer further includes a plurality of color filters at least partially disposed in the plurality of second light transmission openings, he plurality of color filters include first color filters, second color filters and third color filters, orthographic projections of sub-pixel openings of the first sub-pixels on the base substrate are located within orthographic projections of the first color filters on the base substrate, orthographic projections of sub-pixel openings of the second sub-pixels on the base substrate are located within orthographic projections of the second color filters on the base substrate, and orthographic projections of sub-pixel openings of the third sub-pixels on the base substrate are located within orthographic projections of the third color filters on the base substrate.

For example, in the display substrate provided by at least one embodiment of the present disclosure, at least part of the plurality of third light transmission openings is located between second light transmission openings corresponding to the first sub-pixel and the third sub-pixel adjacent to each other, and a minimum distance between the at least part of the plurality of third light transmission openings and the second light transmission opening corresponding to the first sub-pixel is a first distance, a minimum distance between the at least part of the plurality of third light transmission openings and the second light transmission opening corresponding to the third sub-pixel is a second distance, and the first distance is different from the second distance.

For example, in the display substrate provided by at least one embodiment of the present disclosure, the first sub-pixels and the third sub-pixels are disposed in multiple rows and multiple columns, a plurality of first sub-pixels and a plurality of third sub-pixels in a same column are disposed alternately, and one third light transmission opening is disposed between the second light transmission openings corresponding to the first sub-pixel and the third sub-pixel adjacent to each other in the same column.

For example, in the display substrate provided by at least one embodiment of the present disclosure, the second distance between the one third light transmission opening and the second light transmission opening corresponding to the third sub-pixel is smaller than the first distance between the one third light transmission opening and the second light transmission opening corresponding to the first sub-pixel.

For example, in the display substrate provided by at least one embodiment of the present disclosure, for the sub-pixel opening and the third color filter corresponding to the third sub-pixel, an orthographic projection of the sub-pixel opening on the base substrate is located within an orthographic projection of the third color filter on the base substrate, a distance between a boundary of the orthographic projection of the sub-pixel opening on the base substrate and a boundary of the orthographic projection of the third color filter on the base substrate at a side close to the one third light transmission opening is smaller than a distance between the boundary of the orthographic projection of the sub-pixel opening on the base substrate and the boundary of the orthographic projection of the third color filter on the base substrate at a side away from the one third light transmission opening.

For example, in the display substrate provided by at least one embodiment of the present disclosure, for the sub-pixel opening and the second light transmission opening corresponding to the third sub-pixel, the orthographic projection of the sub-pixel opening on the base substrate is located within an orthographic projection of the second light transmission opening on the base substrate, and a distance between the boundary of the orthographic projection of the sub-pixel opening on the base substrate and a boundary of the orthographic projection of the second light transmission opening on the base substrate at a side close to the one third light transmission opening is smaller than a distance between the boundary of the orthographic projection of the sub-pixel opening on the base substrate and the boundary of the orthographic projection of the second light transmission opening on the base substrate at a side away from the one third light transmission opening.

For example, in the display substrate provided by at least one embodiment of the present disclosure, for the sub-pixel opening and the first color filter corresponding to the first sub-pixel, the orthographic projection of the sub-pixel opening on the base substrate is located within an orthographic projection of the first color filter on the base substrate, and a distance between the boundary of the orthographic projection of the sub-pixel opening on the base substrate and a boundary of the orthographic projection of the first color filter on the base substrate at a side close to the one third light transmission opening is substantially equal to a distance between the boundary of the orthographic projection of the sub-pixel opening on the base substrate and the boundary of the orthographic projection of the first color filter on the base substrate at the side away from the one third light transmission opening.

For example, in the display substrate provided by at least one embodiment of the present disclosure, one first sub-pixel, two second sub-pixels and one third sub-pixel constitute one repeating unit, and a plurality of repeating units are disposed in an array, a plurality of second sub-pixels in the plurality of repeating units are arranged in multiple rows and multiple columns, and the one third light transmission opening is further disposed between second light transmission openings corresponding to adjacent second sub-pixels in a row direction.

For example, in the display substrate provided by at least one embodiment of the present disclosure, the first sub-pixels are red sub-pixels, the second sub-pixels are green sub-pixels, and the third sub-pixels are blue sub-pixels; and the first color filters are red filters, the second color filters are green filters, and the third color filters are blue filters.

For example, in the display substrate provided by at least one embodiment of the present disclosure, each of the plurality of repeating units is correspondingly disposed with two first light transmission openings and two third light transmission openings; and orthographic projections of the two first light transmission openings on the base substrate are respectively located within orthographic projections of the two third light transmission openings on the base substrate.

For example, in the display substrate provided by at least one embodiment of the present disclosure, each of the plurality of repeating units is correspondingly disposed with two first light transmission openings, and each of the plurality of repeating units or every plurality of repeating units is correspondingly disposed with one third light transmission opening, orthographic projections of a part of the plurality of first light transmission openings on the base substrate are respectively within orthographic projections of the plurality of third light transmission openings on the base substrate.

For example, the display substrate provided by at least one embodiment of the present disclosure further includes a spacer layer disposed on a side of the pixel definition layer away from the base substrate, wherein the spacer layer includes a plurality of spacers, orthographic projections of the plurality of spacers on the base substrate are respectively located between orthographic projections of sub-pixel openings of adjacent second sub-pixels in a column direction on the base substrate, and are respectively located between orthographic projections of sub-pixel openings of adjacent first sub-pixels and third sub-pixels in a row direction on the base substrate.

For example, in the display substrate provided by at least one embodiment of the present disclosure, a light transmittance of a material of the spacer layer is less than 5%.

For example, in the display substrate provided by at least one embodiment of the present disclosure, a light transmittance of a material of the pixel definition layer is less than 5%.

For example, the display substrate provided by at least one embodiment of the present disclosure further includes an encapsulation layer disposed on a side of the light-emitting device away from the base substrate and a touch layer disposed on a side of the encapsulation layer away from the base substrate, the black matrix layer is disposed on a side of the encapsulation layer away from the base substrate; the black matrix layer is disposed on a side of the touch layer away from the base substrate, the touch layer includes a plurality of touch lines, and orthographic projections of the plurality of touch lines on the base substrate do not overlap with orthographic projections of the plurality of first light transmission openings on the base substrate.

For example, in the display substrate provided by at least one embodiment of the present disclosure, the first sub-pixels and the third sub-pixels are disposed in multiple rows and multiple columns, a plurality of first sub-pixels and a plurality of third sub-pixels in a same column are disposed alternately, and at least part of the plurality of touch lines has a gap between the first sub-pixel and the third sub-pixel that are adjacent to each other and in a same column.

For example, in the display substrate provided by at least one embodiment of the present disclosure, at least part of the plurality of touch lines has a gap at a side close to the third sub-pixel or at a side close to the first sub-pixel among the first sub-pixel and the third sub-pixel that are adjacent to each other and in the same column; or at least part of the plurality of touch lines has gaps at both the side close to the third sub-pixel and the side close to the first sub-pixel among the first sub-pixel and the third sub-pixel adjacent to each other and in the same column.

For example, in the display substrate provided by at least one embodiment of the present disclosure, in a same direction parallel to the base substrate, the plurality of touch lines are at different distances from at least two of the first color filters, the second color filters and the third color filters.

For example, in the display substrate provided by at least one embodiment of the present disclosure, an orthographic projection of a circuit pattern of the pixel driving circuit layer on the base substrate is not overlapped with orthographic projections of the plurality of first light transmission openings on the base substrate.

At least one embodiment of the present disclosure further provides a display device including the display substrate provided by the embodiment of the present disclosure and a sensor. The sensor is disposed on a side of the base substrate of the display substrate away from the light-shielding layer, wherein in a direction perpendicular to the base substrate, the sensor is overlapped with at least one of the plurality of first light transmission openings.

At least one embodiment of the present disclosure further provides a display substrate having a plurality of sub-pixels. The plurality of sub-pixels include first sub-pixels, second sub-pixels, and third sub-pixels; the first sub-pixels and the third sub-pixels are disposed alternately along a row direction to form a plurality of first pixel rows, and the first sub-pixels and the third sub-pixels in a same column among the plurality of first pixel rows are disposed alternately, the second sub-pixels are disposed side by side along the row direction to form a plurality of second pixel rows; and the display substrate includes a base substrate, a pixel driving circuit layer, and a pixel definition layer. The pixel driving circuit layer is disposed on the base substrate. The pixel definition layer is disposed on a side of the pixel driving circuit layer away from the base substrate, and includes a plurality of sub-pixel openings, wherein each of the plurality of sub-pixels includes a pixel driving circuit disposed in the pixel driving circuit layer and a light-emitting device at least partially disposed in one of the plurality of sub-pixel openings, and a black matrix layer including a plurality of first openings and a plurality of second openings, wherein orthographic projections of the plurality of sub-pixel openings on the base substrate are respectively at least partially overlapped with orthographic projections of the plurality of first openings on the base substrate, so that light emitted by light-emitting devices of the plurality of sub-pixels can exit through the plurality of first openings; and the plurality of second openings are respectively disposed between the first openings corresponding to the first sub-pixels and the third sub-pixels adjacent in the column direction.

For example, in the display substrate provided by at least one embodiment of the present disclosure, the pixel driving circuit layer includes first signal lines and second signal lines disposed parallel to each other and arranged periodically, the first signal lines and the second signal lines are configured to provide different electrical signals to the plurality of sub-pixels, and orthographic projections of the plurality of second openings on the base substrate are respectively located between an orthographic projection of one of the first signal lines on the base substrate and an orthographic projection of one of the second signal lines closest to the one of the first signal lines on the base substrate.

For example, in the display substrate provided by at least one embodiment of the present disclosure, the first signal lines are light-emitting control signal lines, and the second signal lines are reset control lines.

For example, in the display substrate provided by at least one embodiment of the present disclosure, the plurality of sub-pixels include a first row of sub-pixels and a second row of sub-pixels adjacent to the first row of sub-pixels and located at a next tier of the first row of sub-pixels, pixel driving circuits of the first row of sub-pixels share one light emitting control signal line of the light-emitting control signal lines and one reset control line of the reset control lines, and pixel driving circuits of the second row of sub-pixels share one light-emitting control signal line of the light-emitting control signal lines and one reset control line of the reset control lines, wherein orthographic projections of a row of second openings on the base substrate are located between an orthographic projection of the one light-emitting control signal line shared by the pixel driving circuits of the first row of sub-pixels on the base substrate and an orthographic projection of the one reset control line shared by the pixel driving circuits of the second row of sub-pixels on the base substrate.

For example, in the display substrate provided by at least one embodiment of the present disclosure, the driving circuit layer includes third signal lines disposed in parallel and arranged periodically, the third signal lines cross the first signal lines and the second signal lines respectively, the third signal lines are configured to provide power supply signals to the plurality of sub-pixels, the third signal lines include hollow parts, and the orthographic projections of the second openings on the base substrate are located within orthographic projections of the hollow parts on the base substrate.

For example, in the display substrate provided by at least one embodiment of the present disclosure, for one of the plurality of second openings and first openings corresponding to the first sub-pixel and the third sub-pixel adjacent to the one of the plurality of second openings, a line connecting centers of the first openings corresponding to the first sub-pixel and the third sub-pixel that are adjacent to the one of the plurality of second openings passes through the one of the plurality of second openings.

For example, in the display substrate provided by at least one embodiment of the present disclosure, a distance between a center of the one of the plurality of second openings and a center of the first opening corresponding to the first sub-pixel is different from a distance between the center of the one of the plurality of second openings and a center of the first opening corresponding to the third sub-pixel.

For example, in the display substrate provided by at least one embodiment of the present disclosure, the plurality of second openings are respectively disposed between first openings corresponding to adjacent second sub-pixels in the row direction.

For example, in the display substrate provided by at least one embodiment of the present disclosure, for one of the plurality of second openings and the first openings corresponding to the second sub-pixels adjacent to the one of the plurality of second openings, a line connecting centers of the first openings corresponding to the second sub-pixels adjacent to the one of the plurality of second openings passes through the one of the plurality of the second openings.

For example, in the display substrate provided by at least one embodiment of the present disclosure, distances between a center of the one of the plurality of second openings and centers of the first openings corresponding to the second sub-pixels adjacent to the one of the plurality of second openings are substantially the same.

For example, in the display substrate provided by at least one embodiment of the present disclosure, the black matrix layer further includes a plurality of color filters at least partially disposed in the plurality of first openings, the plurality of color filters include first color filters, second color filters and third color filters, the orthographic projections of the sub-pixel openings of the first sub-pixels on the base substrate are located within orthographic projections of the first color filters on the base substrate, the orthographic projections of the sub-pixel openings of the second sub-pixels on the base substrate are located within orthographic projections of the second color filters on the base substrate, and the orthographic projections of the sub-pixel openings of the third sub-pixels on the base substrate are located within orthographic projections of the third color filters on the base substrate.

For example, in the display substrate provided by at least one embodiment of the present disclosure, for one of the plurality of second openings and first openings corresponding to the first sub-pixel and the third sub-pixel adjacent to the one of the plurality of second openings, a distance between the center of the one of the plurality of second openings and a center of the first opening corresponding to the first sub-pixel is greater than a distance between the center of the one of the plurality of second openings and a center of the first opening corresponding to the third sub-pixel.

For example, in the display substrate provided by at least one embodiment of the present disclosure, for a sub-pixel opening and a third color filter corresponding to the third sub-pixel, a distance between a boundary of an orthographic projection of the sub-pixel opening on the base substrate and a boundary of an orthographic projection of the third color filter on the base substrate at a side close to the one of the plurality of second openings is smaller than a distance between a boundary of the orthographic projection of the sub-pixel opening on the base substrate and a boundary of the orthographic projection of the third color filter on the base substrate at a side away from the one of the plurality of second openings.

For example, in the display substrate provided by at least one embodiment of the present disclosure, the first sub-pixels are red sub-pixels, the second sub-pixels are green sub-pixels, and the third sub-pixels are blue sub-pixels.

For example, the display substrate provided by at least one embodiment of the present disclosure further includes a light-shielding layer disposed between the base substrate and the pixel driving circuit layer, and including a plurality of third openings, orthographic projections of at least part of the third openings on the base substrate are respectively located within the orthographic projections of the plurality of second openings on the base substrate.

For example, in the display substrate provided by at least one embodiment of the present disclosure, orthographic projections of the third openings on the base substrate are not overlapped with orthographic projections of the first signal lines and the second signal lines on the base substrate, the orthographic projections of the third openings on the base substrate are located within the orthographic projections of the hollow parts on the base substrate.

For example, in the display substrate provided by at least one embodiment of the present disclosure, one first sub-pixel, two second sub-pixels and one third sub-pixel constitute a repeating unit, and a plurality of repeating units are arranged in an array, and each of the plurality of repeating units is correspondingly disposed with two third openings.

### BRIEF DESCRIPTION OF THE DRAWINGS

In order to clearly illustrate the technical solution of the embodiments of the present disclosure, the drawings of the embodiments will be briefly described below. It is obvious that the following described drawings are only related to some embodiments of the present disclosure and are not construed as any limitation to the present disclosure.

FIG. 1 is a schematic partial cross-sectional view of a display substrate provided by at least one embodiment of the present disclosure;

FIG. 2 is a schematic partial plan view of a light-shielding layer in a display substrate provided by at least one embodiment of the present disclosure;

FIG. 3 is a schematic partial plan view illustrating a stack of a light-shielding layer and a black matrix layer in a display substrate provided by at least one embodiment of the present disclosure;

FIG. 4 is a schematic partial plan view of a stack of a light-shielding layer, a black matrix layer, and a color filter in a display substrate provided by at least one embodiment of the present disclosure;

FIG. 5 is a schematic plan view of a stack of a first light transmission opening and a third light transmission opening in the display substrate provided by at least one embodiment of the present disclosure;

FIG. 6 is a schematic plan view illustrating an arrangement of a plurality of spacers of a spacer layer in a display substrate provided by at least one embodiment of the present disclosure;

FIG. 7 is a diagram illustrating a color separation test result of a display substrate provided by at least one embodiment of the present disclosure;

FIG. 8 is a schematic plan view of a stack of a black matrix layer and a touch layer in a display substrate provided by at least one embodiment of the present disclosure;

FIG. 9 is a schematic plan view of a stack of a spacer layer and a black matrix layer in a display substrate provided by at least one embodiment of the present disclosure;

FIG. 10 to FIG. 21 are schematic plan views of various layers in a display substrate provided by at least one embodiment of the present disclosure;

FIG. 22 is a schematic diagram of an equivalent circuit of an 8T1C pixel driving circuit provided by at least one embodiment of the present disclosure; and

FIG. 23 is a working timing diagram of a pixel driving circuit provided by at least one embodiment of the present disclosure.

### DETAILED DESCRIPTION

In order to make objectives, technical details, and advantages of the embodiments of the present disclosure more clear, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the described object is changed, the relative position relationship may be changed accordingly.

With the development of display technology, products such as full screen or narrow bezel have gradually become the development trend of display products due to their large screen-to-body ratio and ultra-narrow bezel. For products such as smart terminals, it is usually necessary to set up hardware such as a front camera, a fingerprint sensor, a distance sensor, or a light sensor, to realize functions such as taking pictures, face recognition, fingerprint recognition, distance detection, emitting light, and detecting light. In order to increase the screen-to-body ratio, full-screen or narrow-bezel products usually use under-screen camera technology or under-screen fingerprint technology, and sensors such as cameras are placed in an under display camera region of the display substrate. In this case, the under display camera region not only has a certain transmittance, but also has a display function, in this way, full display in camera is realized.

For example, an image sensor for a fingerprint recognition function may be disposed on a non-display side of a display substrate in a display device, In this case, a position of the display substrate corresponding to the image sensor needs to have a certain light transmittance, so that signal light incident from the display side of the display substrate can transmit through the display substrate to reach the image sensor on the non-display side, however, the current display substrate structures are difficult to fully transmit signal light, thus it is necessary to reconfigure part of the structure of the display substrate, so that the display substrate can transmit the signal light.

At least one embodiment of the present disclosure provides a display substrate and a display device, the display substrate has a plurality of sub-pixels, and includes a base substrate, a light-shielding layer, a pixel driving circuit layer and a pixel definition layer; the light-shielding layer is disposed on the base substrate and includes a plurality of first light transmission openings, the pixel driving circuit layer is disposed on a side of the light-shielding layer away from the base substrate, the pixel definition layer is disposed on a side of the pixel driving circuit layer away from the base substrate, and includes a plurality of sub-pixel openings for the plurality of sub-pixels, wherein each of the plurality of sub-pixels includes a pixel driving circuit disposed in the pixel driving circuit layer and a light-emitting device at least partially disposed in one of the plurality of sub-pixel openings, and orthographic projections of the plurality of first light transmission openings on the base substrate are respectively located between orthographic projections of adjacent sub-pixel openings of the plurality of sub-pixel openings on the base substrate.

The light-shielding layer of the display substrate can transmit signal light used for fingerprint recognition at the positions of the first light transmission openings, and block non-signal light such as light emitted by the light-emitting device of the display substrate and ambient light at other positions, to avoid non-signal light from irradiating the image sensor for fingerprint recognition, in this way, the recognition speed and accuracy of the image sensor can be improved.

The display substrate and the display device provided by the embodiments of the present disclosure will be described below through several specific embodiments.

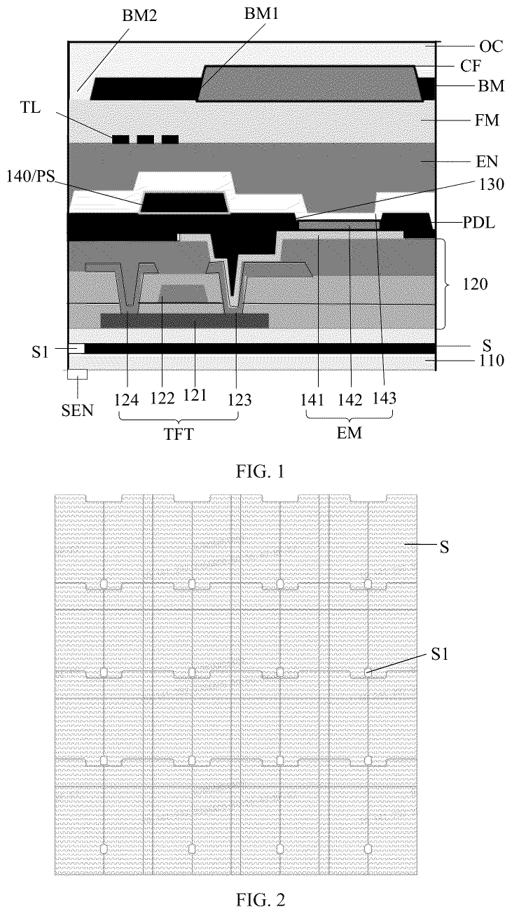

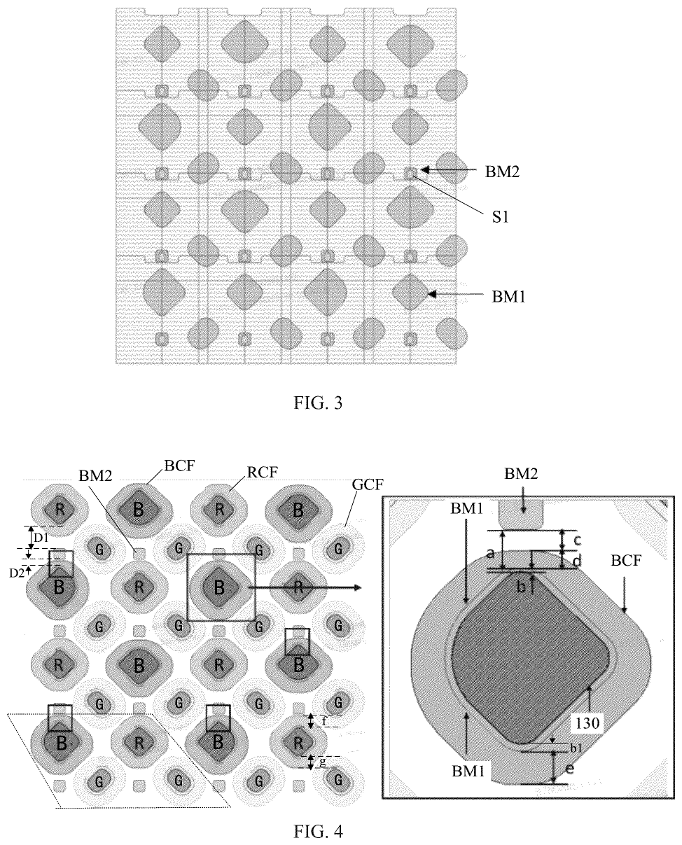

At least one embodiment of the present disclosure provides a display substrate, and FIG. 1 illustrates a schematic partial cross-sectional view of the display substrate, and FIG. 2 illustrates a schematic partial plan view of the light-shielding layer in the display substrate. The display substrate has a plurality of sub-pixels, and includes structures such as a base substrate 110, a light-shielding layer S, a pixel driving circuit layer 120, and a pixel definition layer PDL.

As shown in FIG. 1 and FIG. 2, the light-shielding layer S is disposed on the base substrate 110 and includes a plurality of first light transmission openings S1. The pixel driving circuit layer 120 is disposed on a side of the light-shielding layer S away from the base substrate 110. The pixel definition layer PDL is disposed on a side of the pixel driving circuit layer 120 away from the base substrate 110, and includes a plurality of sub-pixel openings 130 for the plurality of sub-pixels. Each of the plurality of sub-pixels includes a pixel driving circuit disposed in the pixel driving circuit layer 120 and a light-emitting device EM at least partially disposed in one of the sub-pixel openings 130.

For example, each of the pixel driving circuit includes a structure such as a thin film transistor TFT and a storage capacitor (not shown), such as a 3T1C structure, a 4T1C structure, a 5T1C structure, a 5T2C structure, a 6T1C structure, a 7T1C structure or an 8T1C structure, which will be described in detail later. For example, as shown in FIG. 1, the thin film transistor TFT includes structures such as an active layer 121, a gate electrode 122, a first electrode 123 and a second electrode 124. The light-emitting device EM includes a first electrode 141, a light-emitting material layer 142 and a second electrode 143. For example, the first electrode 141 serves as an anode and is electrically connected with the first electrode 123 of the thin film transistor TFT. The light-emitting material layer 142 includes an organic light-emitting material, and is configured to emit monochromatic light or white light. The second electrode 143 serves as a cathode, for example formed as a surface electrode, that is, the second electrodes 143 of the plurality of sub-pixels are continuously disposed in a planar shape to cover the base substrate 110 as a whole; or in some embodiments, the second electrode 143 may have a pattern directly facing the first electrode 141 at the position where the display substrate needs to increase light transmittance, that is, the second electrode 143 is patterned to increase the light transmittance of the display substrate at this position.

For example, as shown in FIG. 1, orthographic projections of the plurality of first light transmission openings S1 on the base substrate 110 are respectively located between orthographic projections of adjacent sub-pixel openings 130 of the plurality of sub-pixel openings 130 on the base substrate 110.

For example, the material of the light-shielding layer S may be a metal material such as copper, aluminum, or an alloy material, alternatively, in some embodiments, the light-shielding layer S may also be a light-shielding layer formed by adding black dye to a resin material, so as to fully realize the light-shielding effect.

In the embodiments of the present disclosure, the light-shielding layer S can transmit the signal light used for fingerprint recognition at the first light transmission opening S1, and block non-signal light such as the light emitted by the light-emitting device EM of the display substrate and ambient light at other positions, to prevent non-signal light from irradiating on the image sensor disposed on the non-display side of the display substrate, in this way, the recognition speed and accuracy of the image sensor can be improved.

For example, in some embodiments, as shown in FIG. 1, the display substrate further includes a black matrix layer BM disposed on the side of the light-emitting device EM away from the base substrate 110. For example, FIG. 3 illustrates a schematic view of the black matrix layer BM of the display substrate stacked on the light-shielding layer S, and FIG. 4 illustrate a schematic view of a stack of the black matrix layer BM, a pixel definition layer PDL and a color filter (described later) of the display substrate.

For example, as shown in FIG. 3 and FIG. 4, the black matrix layer BM includes a plurality of second light transmission openings BM1 and a plurality of third light transmission openings BM2, the orthographic projections of the plurality of sub-pixel openings 130 on the base substrate 110 are respectively at least partially overlapped with orthographic projections of the plurality of second light transmission openings BM1 on the base substrate 110, for example, the orthographic projections of the plurality of sub-pixel openings 130 on the base substrate 110 are respectively located inside the orthographic projections of the plurality of second light transmission openings BM1 on the base substrate 110. For example, as shown in FIG. 4, a distance b (b1) between the orthographic projection of the sub-pixel opening 130 on the base substrate 110 and the orthographic projection of the second light transmission opening BM1 on the base substrate 110 is in a range of 1 μm to 6.5 μm, such as, 1 micron to 5 microns, such as 1 micron to 3.5 microns, such as 1 micron to 2 microns, such as 1.0 micron, 1.2 microns, 1.5 microns, 1.7 microns or 2.0 microns, or the like.

For example, as shown in FIG. 3 and FIG. 4, a plurality of third light transmission openings BM2 are respectively disposed between adjacent second light transmission openings BM1 among the plurality of second light transmission openings BM1, orthographic projections of at least part of the first light transmission openings S1 among the plurality of first light transmission openings S1 on the base substrate 110 are respectively at least partially overlapped with the orthographic projections of the plurality of third light transmission openings BM2 on the base substrate 110.

In this way, the first light transmission openings S1 and the third light transmission openings BM2 form sleeve holes to transmit, for example, signal light for fingerprint recognition, In this case, an image sensor SEN (or a sensor such as a camera, a distance sensor, an infrared sensor, etc.) may be disposed on a side of the base substrate 110 away from the light-emitting device EM, and the image sensor SEN can receive signal light transmitting through the third light transmission openings BM2 and the first light transmission openings S1 to perform texture collection and recognition functions.

For example, in some embodiments, the pixel driving circuit layer includes a plurality of metal layers, such as metal layers where the gate electrode 122, the first electrode 123, the second electrode 124, and so on are located, orthographic projections of circuit patterns formed by these metal layers on the base substrate 110 are not overlapped with the orthographic projections of the plurality of first light transmission openings S1 on the base substrate 110, and also are not overlapped with the orthographic projections of the third light transmission openings BM2 on the base substrate 110, so as to avoid the circuit patterns affecting transmission of signal light.

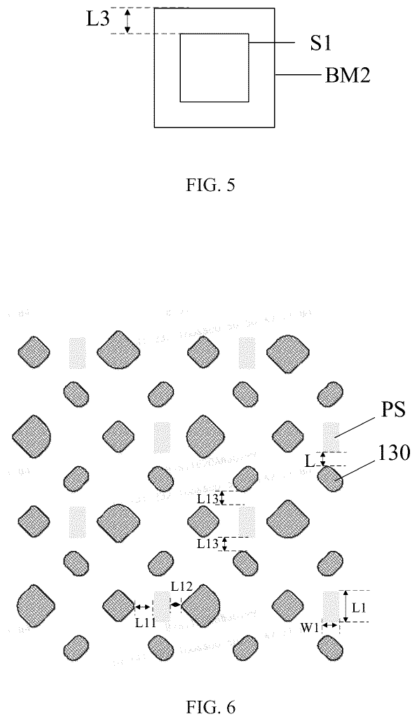

For example, as shown in FIG. 3, the orthographic projections of at least part of the first light transmission openings S1 among the plurality of first light transmission openings S1 on the base substrate 110 are respectively located inside the orthographic projections of the plurality of third light transmission openings BM2 on the base substrate 110. For example, FIG. 5 illustrates a schematic diagram of a stack of a first light transmission opening S1 and a corresponding third light transmission opening BM2, as shown in FIG. 5, a distance L3 between a boundary of the orthographic projections of at least part of the plurality of first light transmission openings S1 on the base substrate 110 and a boundary of the orthographic projections of the plurality of third light transmission openings BM2 on the base substrate 110 is in a range of 0.5 microns to 1.5 microns, such as 0.8 microns, 1.0 microns, 1.2 microns or 1.5 microns.

For example, in some embodiments, as shown in FIG. 1 and FIG. 4, the plurality of sub-pixels includes first sub-pixels R, second sub-pixels G, and third sub-pixels B, the black matrix layer BM further includes a plurality of color filters CF at least partially disposed in the plurality of second light transmission openings BM2, and the plurality of color filters CF include first color filters RCF, second color filters GCF, and third color filters BCF.

Orthographic projections of sub-pixel openings 130 of the first sub-pixels R on the base substrate 110 are located within orthographic projections of the first color filters RCF on the base substrate 110, so that light emitted by light-emitting devices of the first sub-pixels R can exit through the first color filters RCF. Orthographic projections of the sub-pixel openings 130 of the second sub-pixels G on the base substrate 110 are located within orthographic projections of the second color filters GCF on the base substrate 110, so that light emitted by light-emitting devices of the second sub-pixels G can exit through the second color filters GCF. Orthographic projections of sub-pixel openings 130 of the third sub-pixels B on the base substrate 110 are located within orthographic projections of the third color filters BCF on the base substrate 110, so that light emitted by light-emitting devices of the third sub-pixels B can be emitted through the third color filters BCF.

For example, in some other embodiments, the display substrate may further include a color filter layer disposed on a side of the black matrix layer BM away from the base substrate, and the color filter layer has a grid structure. For example, the color filter layer includes at least one of a first color filter layer (such as a red filter layer), a second color filter layer (such as a green filter layer) and a third color filter layer (such as a blue filter layer). In this case, the first color filter layer is hollowed out at the second light transmission openings BM1 corresponding to the second sub-pixels G and the third sub-pixels B; the second color filter layer is hollowed out at the second light transmission openings BM1 corresponding to the first sub-pixels R and the third sub-pixels B; and the third color filter layer is hollowed out at the second light transmission openings BM1 corresponding to the first sub-pixels R and the second sub-pixels G. In this way, reflectivity of light in the display substrate can be further reduced. For example, the color filter layer having a grid structure may further have openings corresponding to the plurality of third light transmission openings BM2.

For example, as shown in FIG. 4, at least part of the plurality of third light transmission openings BM2 are located between the second light transmission openings BM1 corresponding to the adjacent first sub-pixels R and third sub-pixels B, and a minimum distance between the at least part of the plurality of third light transmission openings BM2 and the second light transmission openings BM1 corresponding to the first sub-pixels R is a first distance D1, a minimum distance between the at least part of the plurality of third light transmission openings BM2 and the second light transmission openings BM1 corresponding to the third sub-pixels B is a second distance D2, and the first distance D1 is different from the second distance D2. For example, the first distance D1 is smaller than the second distance D2, that is, the third light transmission openings BM2 located between the adjacent first sub-pixels R and the third sub-pixels B are closer to the third sub-pixels B.

For example, as shown in FIG. 4, the first sub-pixels R and the third sub-pixels B are disposed in multiple rows and multiple columns, the plurality of first sub-pixels R and the plurality of third sub-pixels B located in a same column are alternately arranged, and one third light transmission opening BM2 is disposed between the second light transmission openings BM1 corresponding to the adjacent first sub-pixel R and third sub-pixel B in the same column, that is, the third light transmission openings BM2 are disposed between the second light transmission openings BM1 of the first sub-pixels R and the third sub-pixels B that are adjacent in the column direction.

For example, FIG. 4 further illustrates an enlarged schematic diagram of a sub-pixel opening 130 corresponding to a third sub-pixel B, a second light transmission opening BM1, a third color filter BCF and an adjacent third light transmission opening BM2, the structures shown in other framed areas in FIG. 4 are basically the same as the enlarged part. As shown in FIG. 4, for the sub-pixel opening 130 and the third color filter BCF corresponding to the third sub-pixel B, the orthographic projection of the sub-pixel opening 130 on the base substrate 110 is located inside the orthographic projections of the third color filter BCF on the base substrate 110, and a distance b+d between a boundary of the orthographic projection of the sub-pixel opening 130 on the base substrate 110 and a boundary of the orthographic projection of the third color filter BCF on the base substrate 110 at a side close to the adjacent third light transmission opening BM2 is smaller than a distance b1+e between the boundary of the orthographic projection of the sub-pixel opening 130 on the base substrate 110 and the boundary of the orthographic projection of the third color filter BCF on the base substrate 110 at a side away from the third light transmission opening BM2, that is, the third color filter BCF is shifted toward a direction away from the third light transmission opening BM2, so as to avoid the third color filter BCF covering the third light transmission opening BM2 due to alignment errors during the manufacturing process.

For example, as shown in FIG. 4, for the sub-pixel opening 130 and the second light transmission opening BM1 corresponding to the third sub-pixel B, the orthographic projection of the sub-pixel opening 130 on the base substrate 110 is located inside the orthographic projection of the second light transmission opening BM1 on the base substrate 110, a distance b between the boundary of the orthographic projection of the sub-pixel opening 130 on the base substrate 110 and the boundary of the orthographic projection of the second light transmission opening BM1 on the base substrate 110 at the side close to the third light transmission opening BM2 is smaller than a distance b1 between the boundary of the orthographic projection of the sub-pixel opening 130 on the base substrate 110 and the boundary of the orthographic projection of the second light transmission opening BM1 on the base substrate 110 at the side away from the third light transmission opening BM2, that is, the second light transmission opening BM1 is also shifted toward a direction away from the third light transmission opening BM2. For example, in some embodiments, b is in a range of 0.5 μm to 1.5 μm, such as 1.0 μm, b1 is in a range of 1.0 μm to 2.0 μm, such as 1.5 μm; or b is 1.2 μm, b1 is 1.7 μm.

For example, as shown in FIG. 4, for the second light transmission opening BM1 corresponding to the third sub-pixel B and the adjacent third light transmission opening BM2, a distance a between the boundary of the orthographic projection of the second light transmission opening BM1 on the base substrate 110 and the boundary of the orthographic projection of the third light transmission opening BM2 on the base substrate 110 is greater than or equal to 4 microns, if the distance between the second light transmission opening BM1 and the third light transmission opening BM2 is too small, on the one hand, the light emitted by the light-emitting device EM may leak into the third light transmission opening BM2 to form interference, on the other hand, during the manufacturing process, the black matrix layer is easily opened at the second light transmission opening BM1 and the third light transmission opening BM2, which may be difficult to form the second light transmission opening BM1 and the third light transmission opening BM2 that are separated from each other.

For example, as shown in FIG. 4, for the third color filter BCF corresponding to the third sub-pixel B and the adjacent third light transmission opening BM2, a distance c between the boundary of the orthographic projection of the third color filter BCF on the base substrate 110 and the boundary of the orthographic projection of the third light transmission opening BM2 on the base substrate 110 is greater than or equal to 0, for example greater than 0.5 microns, so that the third color filter BCF will not cover the third light transmission opening BM2, thereby avoiding interference to the signal light transmitted through the third light transmission opening BM2.

For example, as shown in FIG. 4, for the third color filter BCF and the second light transmission opening BM1 corresponding to the third sub-pixel B, at a side close to the third light transmission opening BM2, a distance d between the boundary of the orthographic projection of the third color filter BCF on the base substrate 110 and the boundary of the orthographic projection of the second light transmission opening BM1 on the base substrate 110 is greater than or equal to 2 microns, that is, the distance that the third color filter BCF exceeds the second light transmission opening BM1 is greater than or equal to 2 microns, so as to increase a contact area between the third color filter BCF and the black matrix layer BM, so that peeling of the third color filter BCF from the second light transmission opening BM1 is avoided. For example, at a side away from the third light transmission opening BM2, a distance e between the boundary of the orthographic projection of the third color filter BCF on the base substrate 110 and the boundary of the orthographic projection of the second light transmission opening BM1 on the base substrate 110 is greater than or equal to 3 microns, which is greater than the above-described d. In this way, during the manufacturing process, once the third color filter BCF is peeled off from the second light transmission opening BM1 due to the value of d being small, the whole third color filter BCF can be moved to increase the value of d to improve the peeling phenomenon, and it is ensured that production can continue.

For example, as shown in FIG. 4, for the sub-pixel opening 130 and the first color filter RCF corresponding to the first sub-pixel R, the orthographic projection of the sub-pixel opening 130 on the base substrate 110 are located inside the orthographic projection of the first color filter RCF on the base substrate 110, a distance f between the boundary of the orthographic projection of the sub-pixel opening 130 on the base substrate 110 and the boundary of the orthographic projection of the first color filter RCF on the base substrate 110 at a side close to the third light transmission opening BM2 is substantially equal to a distance g between the boundary of the orthographic projection of the sub-pixel opening 130 on the base substrate 110 and the boundary of the orthographic projection of the first color filter RCF on the base substrate 110 at a side away from the third light transmission opening BM2.

For example, as shown in FIG. 4, one first sub-pixel R, two second sub-pixels G and one third sub-pixel B form a repeating unit, and a plurality of repeating units are disposed in an array, a plurality of second sub-pixels G in the plurality of repeating units are arranged in multiple rows and multiple columns, the third light transmission openings BM2 are further disposed between the second light transmission openings BM1 corresponding to the second sub-pixels G that are adjacent in the row direction. For example, distances between the third light transmission opening BM2 and the second light transmission openings BM1 corresponding to the second sub-pixels G adjacent in the row direction are substantially the same.

For example, in some embodiments, the first sub-pixels R are red sub-pixels, the second sub-pixels G are green sub-pixels, and the third sub-pixels B are blue sub-pixels; the first color filters RCF are red filters, the second color filters GCF are green filters, and the third color filters BCF are blue filters.

Alternatively, in some other embodiments, the first sub-pixels R may also be green sub-pixels or blue sub-pixels, the second sub-pixels G may also be red sub-pixels or blue sub-pixels, and the third sub-pixels B may also be red sub-pixels or green sub-pixels. In this case, a color filter of a corresponding color is disposed on each of the sub-pixels.

For example, in some embodiments, as shown in FIG. 3 and FIG. 4, each of the plurality of repeating units (such as shown in a quadrilateral dotted line box in FIG. 4) is correspondingly disposed with two first light transmission openings S1 and two third light transmission openings BM2; orthographic projections of the two first light transmission openings S1 on the base substrate 110 should respectively be located within orthographic projections of the two third light transmission openings BM2 on the base substrate 110.

For example, in some other embodiments, each of the plurality of the repeating units is correspondingly disposed with two first light transmission openings S1, each of the plurality of repeating units or every plurality of repeating units is correspondingly disposed with one third light transmission opening BM2. In this case, orthographic projections of a part of the first light transmission openings S1 among the plurality of first light transmission openings S1 on the base substrate 110 should be respectively located within the orthographic projections of the plurality of third light transmission openings BM2 on the base substrate 110. That is, in the above-mentioned embodiments, a part of the first light transmission openings S1 and the third light transmission openings BM2 form sleeve holes, for transmitting signal light, while the other first light transmission openings S1 are not used for transmitting the signal light. In this embodiment, since the number of the third light transmission openings BM2 is less than the number of the first light transmission openings S1, positions of the third light transmission openings BM2 can be relatively flexibly disposed, In this case, in some embodiments, the third color filters BCF corresponding to the third sub-pixels B may not be offset disposed as shown in FIG. 4.

For example, as shown in FIG. 1, the display substrate further includes a spacer layer 140 disposed on a side of the pixel definition layer PDL away from the base substrate 110, and the spacer layer 140 includes a plurality of spacers PS. The plurality of spacers PS can support devices such as masks during the manufacturing process of the display substrate.

For example, FIG. 6 illustrates a planar arrangement schematic diagram of a plurality of spacers. As shown in FIG. 6, in some embodiments, orthographic projections of the plurality of spacers PS on the base substrate 110 are respectively located between the orthographic projections of the sub-pixel openings 130 of the second sub-pixels G that are adjacent in the column direction on the base substrate 110, and are respectively located between the orthographic projections of the sub-pixel openings 130 of the adjacent first sub-pixels R and third sub-pixels G in the row direction on the base substrate 110.

For example, in some embodiments, a minimum distance between the plurality of spacers PS and the plurality of sub-pixel openings 130 is L, and 1 micron<L<8 microns, for example, L is 2 microns, 4 microns, 6 microns or 8 microns. In this way, the plurality of spacers PS are spaced apart from the plurality of sub-pixel openings 130 by a certain distance, since sidewalls of the sub-pixel openings 130 usually have a certain inclination angle, if the distances between the plurality of spacers PS and the plurality of sub-pixel openings 130 are too close, the spacers PS may be formed on the sidewalls of the sub-pixel openings 130, which may reduce the heights of the spacers PS relative to the base substrate 110, and make is difficult to achieve a sufficient spacer effect.

For example, in some embodiments, as shown in FIG. 6, planar shapes of at least part of the spacers PS among the plurality of spacers PS are rectangles. For example, a length L1 and a width W1 of each of the rectangles are respectively in a size range of 13 microns to 19 microns, for example, the length L1 may be 15 microns, 17 microns or 19 microns, and the width W1 may be 13 microns, 15 microns or 17 microns, in some embodiments, the planar shapes of at least part of the spacers PS may also be squares, in this case, a side length of each of the squares may be 12 microns, 15 microns, 17 microns, or 19 microns.

For example, in some other embodiments, the planar shapes of at least part of the spacers PS among the plurality of spacers PS may also be circular, in this case, a diameter of each circle may be in a range of 13 microns to 19 microns, such as 15 microns or 17 microns; alternatively, in still other embodiments, the plurality of spacers PS may include a main spacer and an additional spacer, the planar shapes of the main spacer and the additional spacer may be circles, in this case, a sum of diameters of the circles of the main spacer and the additional spacer may be 13 microns to 19 microns, such as 15 microns or 17 microns.

For example, as shown in FIG. 1, in a direction perpendicular to the base substrate 110, that is, in a vertical direction in FIG. 1, heights of the plurality of spacers PS are in a range of 0.5 microns to 2.0 microns, such as 1.0 microns or 1.5 microns, so as to fully realize a spacer function.

For example, as shown in FIG. 6, a shortest distance L11 between an orthographic projection of each of the plurality of spacers PS on the base substrate 110 and the orthographic projection of the sub-pixel opening 130 of the first sub-pixel R among the adjacent first sub-pixel R and third sub-pixel B on the base substrate 110 is greater than a shortest distance L12 between the orthographic projection of the each of the plurality of spacers PS on the base substrate 110 and the orthographic projection of the sub-pixel opening 130 of the third sub-pixel B among the adjacent red sub-pixel R and blue sub-pixel B on the base substrate 110, that is, the spacer PS disposed between the adjacent first sub-pixel R and third sub-pixel B is closer to the sub-pixel opening 130 of the third sub-pixel B than the sub-pixel opening 130 of the first sub-pixel R.

For example, in some embodiments, as shown in FIG. 6, shortest distances L13 between an orthographic projection of each of the plurality of spacers PS on the base substrate 110 and orthographic projections of the sub-pixel openings 130 of the adjacent second sub-pixels G on the base substrate 110 are substantially the same, that is, the distances between a spacer PS disposed between adjacent second sub-pixels G and the sub-pixel openings 130 of the adjacent second sub-pixels G are substantially the same.

For example, in some embodiments, light transmittance of the material of the spacer layer 140 is less than 5%, such as less than 2%. For example, the plurality of spacers PS may be formed of black opaque material, such as a black opaque material formed by doping a black dye in a resin material, the material has a good absorption effect on light, therefore, in a case that the external ambient light is irradiated on the plurality of spacers PS, the external ambient light will not be reflected but absorbed, thus phenomenon of color separation can be weakened or even eliminated.

For example, in some embodiments, the light transmittance of the material of the pixel definition layer PDL is less than 5%, such as less than 2%. For example, the material of the pixel definition layer PDL may be the same as the material of the plurality of spacers PS, in this way, during the manufacturing process, a half-tone mask may be used to form the pixel definition layer PDL and the plurality of spacers PS in a same patterning process, or the pixel definition layer PDL and the plurality of spacers PS may be formed separately using the same or different materials.

In this way, in a case that an external ambient light is irradiated on the pixel definition layer PDL, the external ambient light will not be reflected by the pixel definition layer PDL, thus the phenomenon of color separation can be further weakened or even eliminated.

For example, FIG. 7 illustrates a diagram of actual measurement results of color separation of a display panel provided by an embodiment of the present disclosure, as shown in FIG. 7, the color separation from dark to light colors is very weak, which is not even visible to the naked eye, so that display effect of the display panel can be greatly improved. For example, relative to the CIE1976 Lab coordinate system, the color separation effect can achieve an effect of lab<4 (lab=\sqrt{a²+b²}, a axis represents a relative color of red and green, +a represents red, −a represents green, b axis represents a relative color of yellow and blue, +b represents yellow, −b represents blue), so that using effect of the display substrate under outdoor sunlight can be greatly improved.

For example, as shown in FIG. 1, the display substrate further includes an encapsulation layer EN disposed on a side of the light-emitting device EM away from the base substrate 110, the black matrix layer BM is disposed on a side of the encapsulation layer EN away from the base substrate 110. For example, the encapsulation layer EN may be a composite encapsulation layer, including a first inorganic encapsulation layer, a first organic encapsulation layer, and a second inorganic encapsulation layer (not shown in the figure) sequentially disposed on the light-emitting device EM, to improve the encapsulation effect.

For example, in some embodiments, color filters for the plurality of sub-pixels may be disposed in the composite encapsulation layer, such as between two adjacent sub-encapsulation layers in the composite encapsulation layer. For example, in one example, the composite encapsulation layer includes a first inorganic encapsulation layer, a first organic encapsulation layer, and a second inorganic encapsulation layer sequentially disposed on the light-emitting device EM, in this case, the color filters may be disposed between the first inorganic encapsulation layer and the second inorganic encapsulation layer.

For example, in some embodiments, as shown in FIG. 1, the display substrate further includes a touch layer FM disposed on a side of the encapsulation layer EN away from the base substrate 110, and the black matrix layer BM is disposed on a side of the touch layer FM away from the base substrate 110.

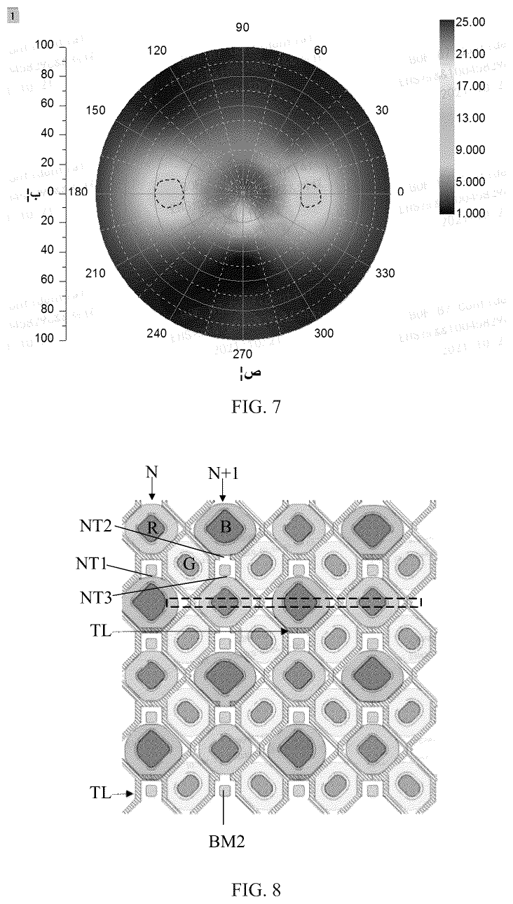

For example, FIG. 8 illustrates a schematic plan view of the touch layer FM, as shown in FIG. 1 and FIG. 8, the touch layer FM includes a plurality of touch lines TL, orthographic projections of the plurality of touch lines TL on the base substrate 110 are not overlapped with the orthographic projections of the plurality of first light transmission openings S1 on the base substrate 110. For example, the orthographic projections of the plurality of touch lines TL on the base substrate 110 are also not overlapped with the orthographic projections of the plurality of second light transmission openings BM1 on the base substrate 110. In this way, the plurality of touch lines TL are blocked by the black matrix layer BM, so as to prevent light from irradiating the touch lines TL and affecting signal transmission performance of the touch lines TL, moreover, the touch lines TL will not block the first light transmission openings S1 and the second light transmission openings BM1, so that influence of the touch lines TL on the transmission of the signal light and the light emitted by the light-emitting devices EM is avoided.

For example, in some embodiments, in a same direction parallel to the base substrate 110, the distances between the plurality of touch lines TL and at least two of the first color filters RCF, the second color filters GCF and the third color filters BCF are different. For example, as shown in FIG. 8, at the position of the dashed box, in the horizontal direction in the figure, the distance between the touch line TL and the third color filter BCF is greater than the distance between the touch line TL and the first color filter RCF. Since the shape and arrangement of the third color filters BCF are irregular, the distance between the touch line TL and the third color filter BCF are set relatively large in this direction, which can avoid the touch lines TL from being overlapped with the third color filters BCF in the direction, or overlapping size can be avoided from being too large.

For example, in some embodiments, as shown in FIG. 8, the first sub-pixels R and the third sub-pixels B are arranged in multiple rows and multiple columns, a plurality of first sub-pixels R and a plurality of third sub-pixels B located in a same column are disposed alternately, for example, at least some of the plurality of touch lines TL have gaps NT1/NT2/NT3 between adjacent first sub-pixels R and third sub-pixels B in a same column. In this way, it can avoid the touch lines TL from shielding the plurality of third light transmission openings BM2.

For example, as shown in FIG. 8, at least part of the plurality of touch lines TL have a gap NT1 at a side close to the third sub-pixel B or a side close to the first sub-pixel R of the adjacent first sub-pixel R and third sub-pixel B in the same column, In this case, at least part of the plurality of touch lines TL have a gap between the adjacent first sub-pixel R and third sub-pixel B in the same column; or at least part of the plurality of touch lines TL have a gap NT2/NT3 on both the side close to the third sub-pixel B and the side close to the first sub-pixel R among the adjacent first sub-pixel R and third sub-pixel B in the same column, in this case, at least part of the plurality of touch lines TL have two gaps between the adjacent first sub-pixel R and third sub-pixel B in the same column. In this way, it can avoid the touch lines TL from shielding the plurality of third light transmission openings BM2.

For example, in some embodiments, as shown in FIG. 8, at least part of the plurality of touch lines TL have a gap NT1 at a side close to the third sub-pixel B or a side close to the first sub-pixel R among the adjacent first sub-pixel R and third sub-pixel B located in the N-th column, and at least part of the plurality of touch lines TL have a gap NT2/NT3 on both a side close to the third sub-pixel B and a side close to the first sub-pixel R among the adjacent first sub-pixel R and third sub-pixel B located in the N+1th column. In this case, in every two adjacent columns of the first sub-pixels R and the third sub-pixels B, one gap is provided between the adjacent first sub-pixel R and third sub-pixel B in one of the two adjacent columns, and two gaps are provided between the adjacent first sub-pixel R and third sub-pixel B in the other one of two adjacent columns. In this way, the plurality of third light transmission openings BM2 can be avoided from being shielded by the touch lines TL.

For example, the display substrate may also include other structures such as a cover plate, the details of which may be referred to related technologies, which will not be repeated herein.

At least one embodiment of the present disclosure further provides a display device, referring to FIG. 1, the display device includes a display substrate provided by an embodiment of the present disclosure and a sensor SEN, the sensor SEN is disposed on a side of the base substrate 110 of the display substrate away from the light-shielding layer, and in a direction perpendicular to the base substrate 110, the sensor SEN is overlapped with at least one of the plurality of first light transmission openings S1. In this way, the sensor can receive the signal light transmitting through the third light transmission openings BM2 and the first light transmission openings S1 to realize corresponding functions. For example, the sensor SEN may be a sensor such as an image sensor, a distance sensor, an infrared sensor, or the like, and the embodiment of the present disclosure does not limit the specific form of the sensor.

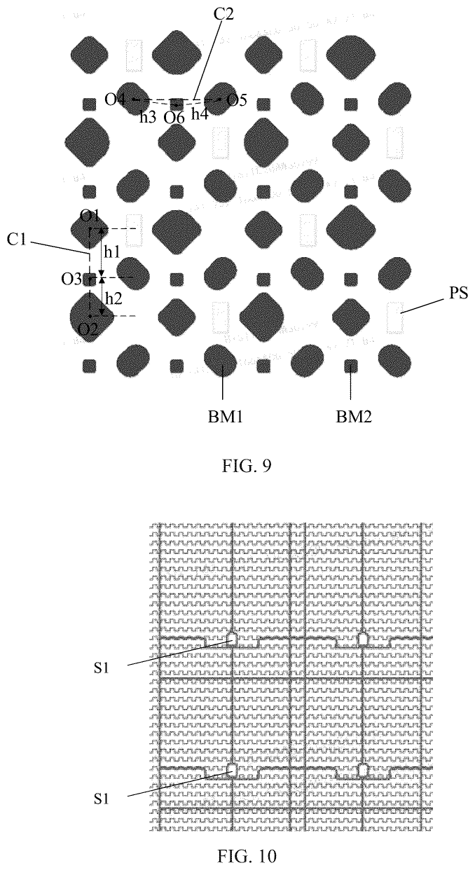

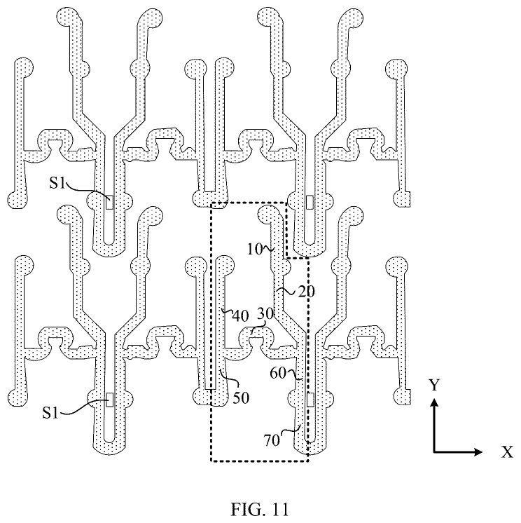

At least one embodiment of the present disclosure provides a display substrate, referring to FIG. 1 and FIG. 9, the display substrate has a plurality of sub-pixels, the plurality of sub-pixels includes first sub-pixels R, second sub-pixels G, and third sub-pixels B; the first sub-pixels R and the third sub-pixels B are disposed alternately along a row direction to form a plurality of rows of first pixel rows, and among the plurality of first pixel rows, the first sub-pixels R and the third sub-pixels B located in a same column are disposed alternately, and the second sub-pixels G are disposed side by side along the row direction to form a plurality of second pixel rows.

Referring to FIG. 1, the display substrate includes a base substrate 110, a pixel driving circuit layer 120, a pixel definition layer PDL and a black matrix layer BM, the pixel driving circuit layer 120 is disposed on the base substrate 110, the pixel definition layer PDL is disposed on a side of the pixel driving circuit layer 120 away from the base substrate 110, and includes a plurality of sub-pixel openings 130 for a plurality of sub-pixels, in which each of the plurality of sub-pixel openings 130 includes a pixel driving circuit disposed in the pixel driving circuit layer 120 and a light-emitting device EM at least partially disposed in the sub-pixel opening 130.

Referring to FIG. 1, the black matrix layer BM includes a plurality of first openings BM1 (the above-mentioned second light transmission openings) and a plurality of second openings BM2 (the above-mentioned third light transmission openings), the orthographic projections of the plurality of sub-pixel openings 130 on the base substrate 110 are respectively at least partially overlapped with the orthographic projections of the plurality of first openings BM1 on the base substrate 110, so that the light emitted by the light-emitting devices EM of the plurality of sub-pixels can exit through the plurality of first openings BM1; the plurality of second openings BM2 are respectively disposed between the first openings BM1 corresponding to the first sub-pixels R and the third sub-pixels B that are adjacent in the column direction.

For example, FIG. 9 illustrates a schematic plan view of a stack of a black matrix layer BM and a spacer layer 140. As shown in FIG. 9, for one second opening BM2 and the first openings BM1 corresponding to the first sub-pixel R and the third sub-pixel B adjacent to the one second opening, a line C1 connecting the centers O1 and O2 of the first openings BM1 corresponding to the adjacent first sub-pixel R and third sub-pixel B passes through the one second opening BM2.

For example, as shown in FIG. 9, the distance h1 between the center O3 of the one second opening BM2 and the center O1 of the first opening BM1 corresponding to the first sub-pixel R is different from the distance h2 between the center O3 of the one second opening BM2 and the center O1 of the first opening BM1 corresponding to the third sub-pixel B, for example, h1 is greater than h2, that is, the second opening BM2 is closer to the first opening BM1 corresponding to the third sub-pixel B than the first opening BM1 corresponding to the first sub-pixel R.

For example, as shown in FIG. 9, a plurality of second openings BM2 are respectively disposed between first openings BM1 corresponding to adjacent second sub-pixels G in the row direction.

For example, as shown in FIG. 9, for one second opening BM2 and the first openings BM1 corresponding to the second sub-pixels G adjacent to the one second opening BM2, a line C2 connecting the centers O4 and O5 of the first openings BM1 corresponding to the adjacent first sub-pixels G passes through the one second opening BM2. For example, as shown in FIG. 9, the distances h3 and h4 between the center O6 of the second opening BM2 and the centers O4 and O5 of the first openings BM1 corresponding to the adjacent second sub-pixels G are substantially the same.

For example, referring to FIG. 1 and FIG. 4, the black matrix layer BM further includes a plurality of color filters CF at least partially disposed in the plurality of first openings BM1, and the plurality of color filters CF includes first color filters RCF, second color filters GCF, and third color filters BCF.

The orthographic projections of the sub-pixel openings 130 of the first sub-pixels R on the base substrate 110 are located within the orthographic projections of the first color filters RCF on the base substrate 110, so that the light emitted by the light-emitting devices of the first sub-pixels R can exit through the first color filters RCF. The orthographic projections of the sub-pixel openings 130 of the second sub-pixels G on the base substrate 110 are located within the orthographic projections of the second color filters GCF on the base substrate 110, so that the light emitted by the light-emitting devices of the second sub-pixels G can exit through the second color filters GCF. The orthographic projections of the sub-pixel openings 130 of the third sub-pixels B on the base substrate 110 are located within the orthographic projections of the third color filters BCF on the base substrate 110, so that the light emitted by the light-emitting devices of the third sub-pixels B can be emitted through the third color filters BCF.

For example, referring to FIG. 4, for the sub-pixel opening 130 and the third color filter BCF corresponding to the third sub-pixel B, the distance b+d between the boundary of the orthographic projection of the sub-pixel opening 130 on the base substrate 110 and the boundary of the orthographic projection of the third color filter BCF on the base substrate 110 at the side close to the second opening BM2 is smaller than the distance b1+e between the boundary of the orthographic projection of the sub-pixel opening 130 on the base substrate 110 and the boundary of the orthographic projection of the third color filter BCF on the base substrate 110 at the side away from the second opening BM2. For other arrangement relationships of the sub-pixel openings 130, the first openings BM1, the second openings BM2 and the third color filters BCF, reference may be made to the above-mentioned embodiments.

For example, the first sub-pixels R are red sub-pixels, the second sub-pixels G are green sub-pixels, and the third sub-pixels B are blue sub-pixels.

For example, referring to FIG. 1 and FIG. 3, the display substrate further includes a light-shielding layer S, the light-shielding layer S is disposed between the base substrate 110 and the pixel driving circuit layer 120, and includes a plurality of third openings S1 (the above-mentioned first light transmission openings S1), the orthographic projections of at least part of the plurality of third openings S1 on the base substrate 110 are respectively located within the orthographic projections of the plurality of second openings BM2 on the base substrate 110.

For example, one first sub-pixel R, two second sub-pixels G and one third sub-pixel B constitute a repeating unit, and a plurality of repeating units are disposed in an array, and each of the plurality of repeating units is correspondingly disposed with two third openings S1. For example, each third opening S1 is correspondingly disposed with one second opening BM2, or in other embodiments, every two or more third openings S1 are correspondingly disposed with one second opening BM2, for details, reference may be made to the foregoing embodiments, which are not repeated herein.

For example, the display substrate may further include other structures, such as a spacer layer, an encapsulation layer, a touch layer, and so on, which may refer to the above embodiments, and details are not repeated herein.

For example, in various embodiments of the present disclosure, the pixel driving circuits may have a 3T1C structure, a 4T1C structure, a 5T1C structure, a 5T2C structure, a 6T1C structure, a 7T1C structure or an 8T1C structure. For example, FIG. 22 is a schematic diagram illustrating an equivalent circuit of an 8T1C pixel driving circuit. As shown in FIG. 22, the pixel driving circuit may include eight transistors (the first transistor T1 to the eighth transistor T8), one storage capacitor C and a plurality of signal lines (such as, a data signal line Data, a first scanning signal line Gate, a second scanning signal line GateN, a reset control signal line Reset, a first initial signal line INIT1, a second initial signal line INIT2, a first power supply line VDD, a second power supply line VSS and a light-emitting control signal line EM).

For example, a gate electrode of the first transistor T1 is connected with the reset control signal line Reset, a first electrode of the first transistor T1 is connected with the second initial signal line INIT2, a second electrode of the first transistor T1 is connected with the fifth node N5. A gate electrode of the second transistor T2 is connected with the first scanning signal line Gate, a first electrode of the second transistor T2 is connected with the fifth node N5, and a second electrode of the second transistor T2 is connected with the third node N3. A gate electrode of the third transistor T3 is connected with the first node N1, a first electrode of the third transistor T3 is connected with the second node N2, and a second electrode of the third transistor T3 is connected with the third node N3. A gate electrode of the fourth transistor T4 is connected with the first scanning signal line Gate, a first electrode of the fourth transistor T4 is connected with the data signal line Data, and a second electrode of the fourth transistor T4 is connected with the second node N2. A gate electrode of the fifth transistor T5 is connected with the light-emitting control signal line EM, a first electrode of the fifth transistor T5 is connected with the first power line VDD, and a second electrode of the fifth transistor T5 is connected with the second node N2. A gate electrode of the sixth transistor T6 is connected with the light-emitting control signal line EM, a first electrode of the sixth transistor T6 is connected with the third node N3, and a second electrode of the sixth transistor T6 is connected with the fourth node N4 (i.e., the first electrode of the light-emitting device). A gate electrode of the seventh transistor T7 is connected with the first scanning signal line Gate or the reset control signal line Reset, a first electrode of the seventh transistor T7 is connected with the first initial signal line INIT1, and a second electrode of the seventh transistor T7 is connected with the fourth node N4. A gate electrode of the eighth transistor T8 is connected with the second scanning signal line GateN, the first electrode of the eighth transistor T8 is connected with the fifth node N5, and the second electrode of the eighth transistor T8 is connected with the first node N1. A first end of the storage capacitor C is connected with the first power line VDD, and a second end of the storage capacitor C is connected with the first node N1.

In some embodiments, the first transistor T1 to the seventh transistor T7 may be N-type thin film transistors, and the eighth transistor T8 may be a P-type thin film transistor; alternatively, the first transistor T1 to the seventh transistor T7 may be P-type thin film transistors, and the eighth transistor T8 may be an N-type thin film transistor.

In some embodiments, the first transistor T1 to the seventh transistor T7 may be Low Temperature Poly Silicon (LTPS) thin film transistors (TFT), and the eighth transistor T8 may be an Indium Gallium Zinc Oxide (IGZO) thin film transistor.

In the above embodiments, compared with the low-temperature polysilicon thin film transistors, the indium gallium zinc oxide thin film transistor generates less leakage current, therefore, disposing the eighth transistor T8 as an indium gallium zinc oxide thin film transistor can significantly reduce the generation of leakage current, so that a problem of low-frequency and low-brightness flickering of the display panel is improved. In addition, the first transistor T1 and the second transistor T2 need not to be set as indium gallium zinc oxide thin film transistors, since a size of the low-temperature polysilicon thin film transistor is generally smaller than a size of the indium gallium zinc oxide thin film transistor, occupied space of the pixel driving circuit in the embodiment of the present disclosure will be relatively small, which is beneficial to improve the resolution of the display panel.

The above-mentioned pixel driving circuit provided by the embodiment of the present disclosure combines good switching characteristics of LTPS-TFT and low leakage characteristics of Oxide-TFT, so that low-frequency driving (1 Hz-60 Hz) can be realized, and the power consumption of the display screen can be greatly reduced.

In some embodiments, second electrodes of the light-emitting devices are connected with the second power supply line VSS, and a signal of the second power supply line VSS is configured to continuously provide a low-level signal, and a signal of the first power line VDD is configured to continuously provide a high-level signal. A signal of the first scanning signal line Gate is a scanning signal in pixel driving circuits of the display row, and a signal of the reset control signal line Reset is a scanning signal in pixel driving circuits of the previous display row, that is, for the n-th display row, the first scanning signal line Gate is Gate (n), the reset control signal line Reset is Gate (n−1), the signal of the reset control signal line Reset of this display row and the signal of the first scanning signal line Gate in the pixel driving circuits of the previous display row may be a same signal, so as to reduce the signal lines of the display panel, so that the narrow frame of the display panel is realized.

In some embodiments, the first scanning signal line Gate, the second scanning signal line GateN, the reset control signal line Reset, the light-emitting control signal line EM, the first initial signal line INIT1 and the second initial signal line INIT2 all extend along a horizontal direction, the second power line VSS, the first power line VDD and the data signal line DATA all extend in a vertical direction.

In some embodiments, at least part of the first initial signal line INIT1, the second initial signal line INIT2, the second power line VSS, and the first power line VDD may be a mesh structure, that is, include both horizontally extending and vertically extending portions.

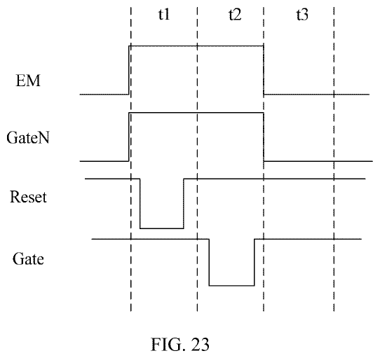

FIG. 23 is a working timing diagram of a pixel driving circuit. The following describes an exemplary embodiment of the present disclosure through the working process of the pixel driving circuit illustrated in FIG. 22, the pixel driving circuit in FIG. 22 includes eight transistors (the first transistor T1 to the eighth transistor T8) and one storage capacitor C, and this embodiment is described by taking the first transistor T1 to the seventh transistor T7 being P-type transistors, the eighth transistor T8 being an N-type transistor, and the gate electrode of the seventh transistor T7 being connected with the first scanning signal line Gate as an example.

For example, in some embodiments, the working process of the pixel driving circuit may include the following stages.

In a first stage t1, which is called a reset stage, the signals of the first scanning signal line Gate, the reset control signal line Reset, the second scanning signal line GateN and the light-emitting control signal line EM are all high-level signals, and the signal of the reset control signal line Reset is a low-level signal. The high-level signal of the light-emitting control signal line EM makes the fifth transistor T5 and the sixth transistor T6 turn off, the high-level signal of the second scanning signal line GateN makes the eighth transistor T8 turn on, and the low-level signal of the reset control signal line Reset makes the first transistor T1 turn on, therefore, a voltage of the first node N1 is reset to a second initial voltage Vinit2 provided by the second initial signal line INIT2, then an electric potential of the reset control signal line Reset is set to be high, and the first transistor T1 is turned off. Since the fifth transistor T5 and the sixth transistor T6 are turned off, the light-emitting device EL does not emit light at this stage.

In a second stage t2, which is called a data writing stage, the signal of the first scanning signal line Gate is a low-level signal, the fourth transistor T4, the second transistor T2 and the seventh transistor T7 are turned on, the data signal line Data outputs a data voltage, the voltage of the fourth node N4 is reset to be a first initial voltage Vinit1 provided by the first initial voltage line INIT1, so that initialization is completed. In this stage, since the first node N1 is at a low-level, the third transistor T3 is turned on. The fourth transistor T4 and the second transistor T2 are turned on, so that the data voltage output by the data signal line Data is provided to the first node N through the turned-on fourth transistor T4, the second node N2, the turned-on third transistor T3, the third node N3, the turned-on second transistor T2, the fifth node N5 and the eighth transistor T8, and a sum of the data voltage output by the data signal line Data and the threshold voltage of the third transistor T3 is charged into the storage capacitor C, a voltage of a second end (the first node N1) of the storage capacitor C is Vdata+Vth, and Vdata is a data voltage output by the data signal line Data, and Vth is a threshold voltage of the third transistor T3. The signal of the light-emitting control signal line EM is a high-level signal, the fifth transistor T5 and the sixth transistor T6 are turned off, so as to ensure that the light-emitting device EL does not emit light.

In a third stage t3, which is called a light-emitting stage, the signals of the first scanning signal line Gate and the reset control signal line Reset are high-level signals, and the signals of the light emitting control signal line EM and the second scanning signal line GateN are both low-level signals. The high-level signal of the reset control signal line Reset turns off the seventh transistor T7, the low-level signal of the light-emitting control signal line EM turns on the fifth transistor T5 and the sixth transistor T6, the power supply voltage output by the first power supply line VDD provides a driving voltage to the first electrode of the light-emitting device EL (that is, the fourth node N4) through the turned-on fifth transistor T5, third transistor T3 and sixth transistor T6, so as to drive the light-emitting device EL to emit light.

During a driving process of the pixel driving circuit, a driving current flowing through the third transistor T3 (that is, the third transistor) is determined by a voltage difference between the gate electrode and the first electrode of the third transistor T3. Since the voltage of the first node N1 is Vdata+Vth, the driving current of the third transistor T3 is:

I=K*(Vgs−Vth)²=K*[(Vdata+Vth−Vdd)−Vth]²=K*[(Vdata−Vdd)]²

wherein, I is the driving current flowing through the third transistor T3, that is, the driving current for driving the light-emitting device EL, K is a constant, Vgs is the voltage difference between the gate electrode and the first electrode of the third transistor T3, Vth is the threshold voltage of the third transistor T3, Vdata is the data voltage output from the data signal line Data, and Vdd is the power supply voltage output from the first power supply terminal VDD.

It can be seen from the above formula that the current I flowing through the light-emitting device EL is independent of the threshold voltage Vth of the third transistor T3, so that influence of the threshold voltage Vth of the third transistor T3 on the current I is eliminated, thereby ensuring the uniformity of brightness.

Based on the above working sequence, the pixel driving circuit eliminates the residual positive charge of the light-emitting device EL after the last light-emitting, so that the gate voltage of the third transistor is compensated, the influence of the threshold voltage drift of the third transistor on the driving current of the light-emitting device EL is avoided, and the uniformity of the displayed image and the display quality of the display panel are improved.

The pixel driving circuit of the embodiment of the present disclosure can adjust the reset voltage of the light-emitting device EL and the reset voltage of the first node N1 respectively by initializing the fourth node N4 to the signal of the first initial signal line INIT1 and by initializing the fifth node N5 to the signal of the second initial signal line INIT2, so that a better display effect can be achieved, and problems such as low-frequency flickering can be improved.

For example, FIG. 10 to FIG. 21 illustrate schematic plan views of sequential stacking of various layers of a display substrate provided by at least one embodiment of the present disclosure.

For example, FIG. 10 illustrates a schematic plan view of the light-shielding layer, and the light-shielding layer includes a plurality of first light transmission openings (third openings) S1.

FIG. 11 illustrates a schematic plan view of the first semiconductor layer stacked after the light-shielding layer, the first semiconductor layer includes active layers of a plurality of thin film transistors. The first semiconductor layer may be made of silicon material, and the silicon material includes amorphous silicon and polysilicon; in some embodiments, the first semiconductor layer may be amorphous silicon a-Si, which is crystallized or laser annealed to form polysilicon.

A range indicated by the dotted box in FIG. 11 is a setting range of the pixel driving circuit of one of the sub-pixels. As shown in FIG. 11, the first semiconductor layer may include a first active layer 10 of the first transistor T1, a second active layer 20 of the second transistor T2, a third active layer 30 of the third transistor T3, a fourth active layer 40 of the fourth transistor T4, a fifth active layer 50 of the fifth transistor T5, a sixth active layer 60 of the sixth transistor T6 and a seventh active layer 70 of the seventh transistor T7. The first active layer 10, the second active layer 20, the third active layer 30, the fourth active layer 40, the fifth active layer 50, the sixth active layer 60 and the seventh active layer 70 are an integral structure connected to each other.

In some embodiments, the shape of the third active layer 30 may be in a shape of “ [symbol] ”, the first active layer 10, the second active layer 20, the fourth active layer 40, the fifth active layer 50, the sixth active layer 60 and the seventh active layer 70 may have a “1” shape.

In some embodiments, in a second direction Y, the first semiconductor layer of any two adjacent columns of sub-pixels is a mirror-symmetrical structure.

In some embodiments, the channel region of the third active layer 30 extends along the row direction, the channel regions of the first active layer 10, the second active layer 20, the fourth active layer 40, the fifth active layer 50, the sixth active layer 60 and the seventh active layer 70 extend in the column direction.

For example, an orthographic projection of the first light transmission opening (third opening) S1 on the base substrate 110 is adjacent to the orthographic projections of the sixth active layer 60 and the seventh active layer 70 on the base substrate 110, accordingly, an orthographic projection of the third light transmission opening (second opening) BM2 on the base substrate 110 is adjacent to the orthographic projections of the sixth active layer 60 and the seventh active layer 70 on the base substrate 110.

In some embodiments, polysilicon (p-Si) may be used for the first semiconductor layer, that is, the first transistor, the second transistor, the third transistor, the fourth transistor, the fifth transistor, the sixth transistor and the seventh transistor may all be LTPS thin film transistors.

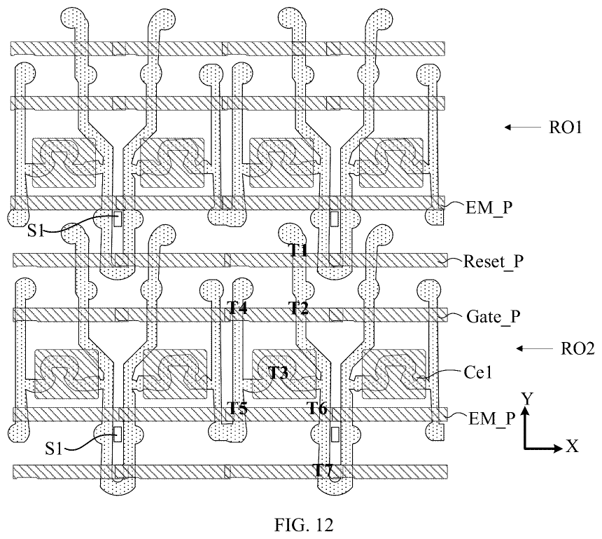

For example, FIG. 12 illustrates a schematic plan view of the first conductive layer stacked after the first semiconductor layer. In some embodiments, as shown in FIG. 12, the first conductive layer may include: a first scanning signal line Gate_P, a reset control signal line Reset_P, a light-emitting control signal line EM_P, and a first electrode plate Ce1 of the storage capacitor C. In some embodiments, the first conductive layer may be referred to as a first gate metal (GATE 1) layer.

In some embodiments, in the second direction Y, the first conductive layer of any two adjacent columns of sub-pixels is a mirror-symmetrical structure.

In some embodiments, the first scanning signal line Gate_P, the reset control signal line Reset_P and the light-emitting control signal line EM_P all extend along a first direction X. In each of the sub-pixels, the reset control signal line Reset_P is located on a side of the first scanning signal line Gate_P away from the light-emitting control signal line EM_P, and a first electrode plate Ce1 of the storage capacitor is disposed between the first scanning signal line Gate_P and the light emitting control signal line EM_P.

For example, the pixel driving circuit layer (such as the above-mentioned first conductive layer) includes a first signal line (such as an light-emitting control signal line EM_P in some embodiments) and a second signal line (such as a reset control line Reset_P in some embodiments) that are disposed parallel to each other and disposed periodically, the first signal line and the second signal line are configured to provide different electrical signals to a plurality of sub-pixels, orthographic projections of a plurality of first light transmission openings (third openings) S1 on the base substrate 110 are respectively located between an orthographic projection of one first signal line (for example, a light-emitting control signal line EM_P) on the base substrate 110 and an orthographic projection of one second signal line (for example, a reset control line Reset_P) closest to the one first signal line on the base substrate 110. Accordingly, orthographic projections of a plurality of third light transmission openings (second openings) BM2 on the base substrate 110 are respectively located between an orthographic projection of one first signal line (for example, a light-emitting control signal line EM_P) on the base substrate 110 and an orthographic projection of one second signal line (for example, a reset control line Reset_P) closest to the one first signal line on the base substrate 110.

For example, the plurality of sub-pixels includes a first row of sub-pixels RO1 and a second row of sub-pixels RO2 adjacent to the first row of sub-pixels RO1 and located at the next tier of the first row of sub-pixels RO1. The pixel driving circuits of the first row of sub-pixels RO1 share one light-emitting control signal line EM_P and one reset control line Reset_P. The pixel driving circuits of the second row of sub-pixels RO2 share one light-emitting control signal line EM_P and one reset control line Reset_P, wherein orthographic projections of a row of first light transmission openings (third openings) S1 on the base substrate 110 are between an orthographic projection of the light-emitting control signal line EM_P shared by the pixel driving circuits of the first row sub-pixels RO1 on the base substrate 110 and an orthographic projection of the reset control line Reset_P shared by the pixel driving circuits of the second row of sub-pixels RO2 on the base substrate 110. Accordingly, orthographic projections of a row of third light transmission openings (second openings) BM2 on the base substrate 110 is between an orthographic projection of the light-emitting control signal line EM_P shared by the pixel driving circuits of the first row of sub-pixels RO1 on the base substrate 110 and an orthographic projection of the reset control line Reset_P shared by the pixel driving circuits of the second row of sub-pixels RO1 on the base substrate 110.

In some embodiments, the first electrode plate Ce1 may be rectangular, and corners of the rectangle may be chamfered, an orthographic projection of the first electrode plate Ce1 on the base substrate 110 and an orthographic projection of the third active layer 30 of the third transistor T3 on the base substrate 110 may have an overlapping region. In some embodiments, the first electrode plate Ce1 also serves as the gate electrode of the third transistor T3.

In some embodiments, a region of the reset control signal line Reset_P overlapped with the first active layer of the first transistor T1 serves as the gate electrode of the first transistor T1, a region of the first scanning signal line Gate_P overlapped with the second active layer of the second transistor T2 serves as the gate electrode of the second transistor T2, a region of the first scanning signal line Gate_P overlapped with the fourth active layer of the fourth transistor T4 serves as the gate electrode of the fourth transistor T4, a region of the light-emitting control signal line EM_P overlapped with the fifth active layer of the fifth transistor T5 serves as the gate electrode of the fifth transistor T5, and an region of the light-emitting control signal line EM_P overlapped with the sixth active layer of the sixth transistor T6 serves as the gate electrode of the sixth transistor T6. For each row of sub-pixels, a region of the reset control signal line Reset_P (the signal of which is the same as the signal of the first scanning signal line Gate_P in the current row of sub-pixels) in the next row of sub-pixels overlapped with the seventh active layer of the seventh transistor T7 in the current row of sub-pixels serves as the gate electrode of the seventh transistor T7.

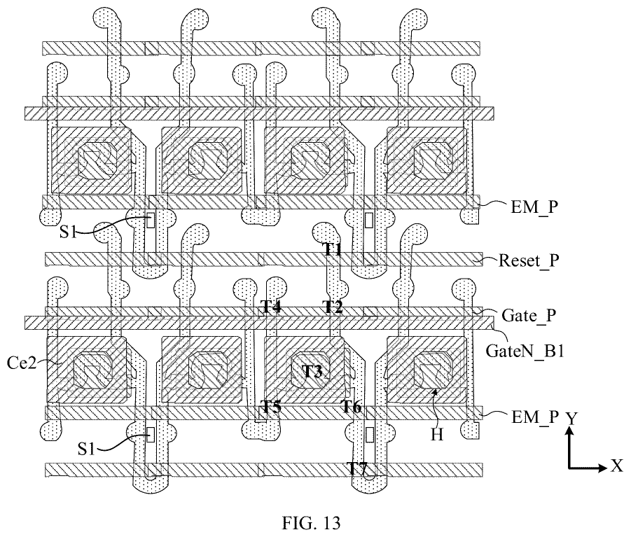

For example, FIG. 13 illustrates a schematic plan view of the second conductive layer stacked after the first conductive layer. As shown in FIG. 13, the second conductive layer includes: a second electrode plate Ce2 of the storage capacitor C and a first branch GateN_B1 of the second scanning signal line GateN. In some embodiments, the second conductive layer may be referred to as a second gate metal (GATE 2) layer.

In some embodiments, in the second direction Y, the second conductive layer of any two adjacent columns of sub-pixels is a mirror symmetrical structure.

In some embodiments, the first branch GateN_B1 of the second scanning signal line GateN extends along the first direction X. In each of the sub-pixels, the second electrode plate Ce2 of the storage capacitor is located between the first branch GateN_B1 of the second scanning signal line GateN and the light-emitting control signal line EM_P.

In some embodiments, an outline of the second electrode plate Ce2 may be rectangular, and corners of the rectangle may be chamfered, and an orthographic projection of the second electrode plate Ce2 on the base substrate 110 is overlapped with an orthographic projection of the first electrode plate Ce1 on the base substrate 110. An opening H is disposed on the second electrode plate Ce2, and the opening H may be located in the middle part of the second electrode plate Ce2. The opening H may have a shape of regular hexagon, so that the second electrode plate Ce2 forms a ring structure. The opening H exposes the third insulating layer covering the first electrode plate Ce1, and an orthographic projection of the first electrode plate Ce1 on the base substrate 110 includes an orthographic projection of the opening H on the base substrate 110. In some embodiments, the opening H is configured to accommodate a subsequently formed fourth via hole, the fourth via hole is located in the opening H and exposes the first electrode plate Ce1, so that the second electrode of the subsequently formed eighth transistor T8 is connected with the first electrode plate Ce1.

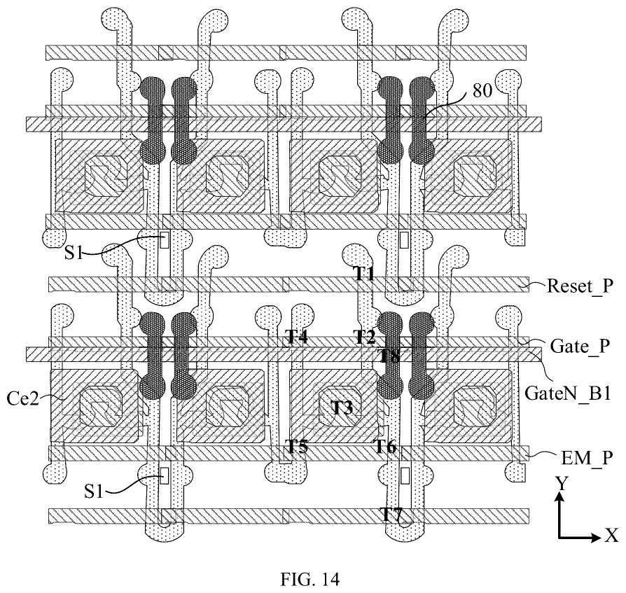

For example, FIG. 14 illustrates a schematic plan view of the second semiconductor layer stacked after the second conductive layer. In some embodiments, as shown in FIG. 14, the second semiconductor layer of each of the sub-pixels may include an eighth active layer 80 of the eighth transistor T8. In some embodiments, the eighth active layer 80 extends along the second direction Y, and a shape of the eighth active layer 80 may have a shape of dumbbell.

In the second direction Y, the second semiconductor layer of any two adjacent columns of sub-pixels is a mirror-symmetrical structure.

In some embodiments, an oxide may be used for the second semiconductor layer, that is, the eighth transistor is an oxide thin film transistor.

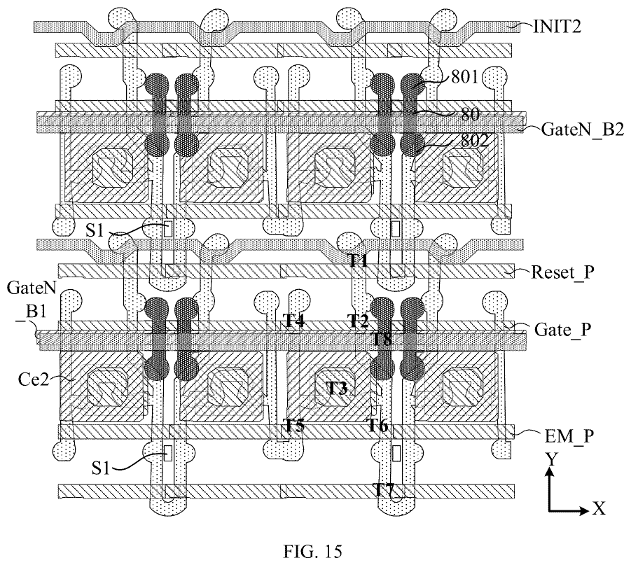

For example, FIG. 15 illustrates a schematic plan view of the third conductive layer stacked after the second conductive layer. As shown in FIG. 15, the third conductive layer includes: a second branch GateN_B2 of the second scanning signal line GateN and a second initial signal line INIT2. In some embodiments, the third conductive layer may be referred to as a third gate metal (GATE3) layer.

In some embodiments, in the second direction Y, the third conductive layer of any two adjacent columns of sub-pixels is a mirror-symmetrical structure.

In some embodiments, the second branch GateN_B2 of the second scanning signal line GateN extends along the first direction X, the second branch GateN_B2 of the second scanning signal line GateN is close to the second branch Gate_B2 of the first scanning signal line Gate. In some embodiments, a region of the second branch GateN_B2 of the second scanning signal line GateN overlapped with the eighth active layer 80 serves as the gate electrode of the eighth transistor.

In some embodiments, an orthographic projection of the second branch GateN_B2 of the second scanning signal line on the base substrate 110 is overlapped with an orthographic projection of the first branch GateN_B1 of the second scanning signal line on the base substrate 110. In some embodiments, the first branch GateN_B1 of the second scanning signal line and the second branch GateN_B2 of the second scanning signal line may be connected by a signal line in a peripheral region.

In some embodiments, the second initial signal line INIT2 extends along the first direction X, in each row of sub-pixels, the second initial signal line INIT2 is disposed on a side of the reset control signal line Reset_P away from the first scanning signal line Gate_P.

For example, an orthographic projection of the first light transmission opening (third opening) S1 on the base substrate 110 is also located between orthographic projections of a light-emitting control signal line EM_P and a second initial signal line INIT2 closest to the light-emitting control signal line EM_P on the base substrate 110. Accordingly, the orthographic projection of the third light transmission opening (second opening) BM2 on the base substrate 110 is also located between the orthographic projections of a light-emitting control signal line EM_P and a second initial signal line INIT2 closest to the light-emitting control signal line EM_P on the base substrate 110.

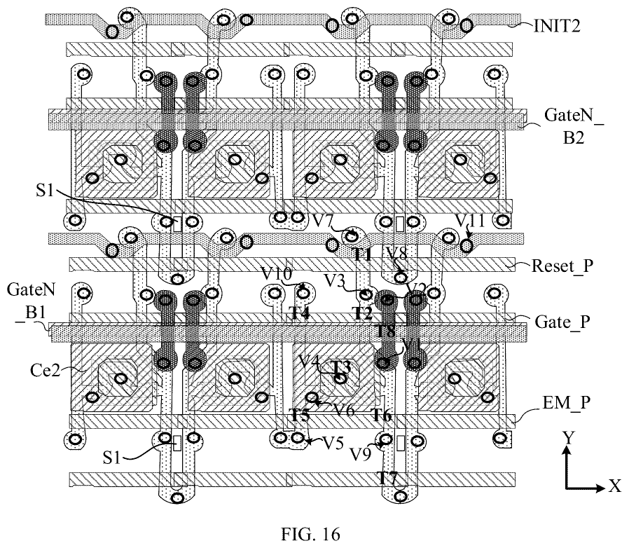

For example, FIG. 16 illustrates a planar distribution view of a plurality of via holes in the insulating layer formed on the third conductive layer. As shown in FIG. 16, a plurality of via holes are disposed in the insulating layer, the plurality of via holes include: a first via hole V1, a second via hole V2, a third via hole V3, a fourth via hole V4, a fifth via hole V5, a sixth via hole V6, a seventh via hole V7, an eighth via hole V8, a ninth via hole V9, a tenth via hole V10 and an eleventh via hole V11.

For example, the first via hole V1 exposes a surface of a second region of the eighth active layer 80. The second via hole exposes a surface of a first region of the eighth active layer 80. The third via hole V3 exposes a surface of a first region of the second active layer. The third via hole V3 is configured such that a first electrode of the subsequently formed second transistor T2 is connected with the second active layer through the third via hole V3.

The fourth via hole V4 is located within an opening H of the second electrode plate Ce2, an orthographic projection of the fourth via hole V4 on the base substrate 110 is within a range of an orthographic projection of the opening H on the base substrate 110, and the fourth via hole V4 exposes a surface of the first electrode plate Ce1. The fourth via hole V4 is configured such that the subsequently formed third connection electrode 43 is connected with the first electrode plate Ce1 through the fourth via hole V4.

The fifth via hole V5 exposes a surface of a first region of the fifth active layer. The fifth via hole V5 is configured such that a first electrode of the subsequently formed fifth transistor T5 is connected with the fifth active layer through the fifth via hole V5.

The sixth via hole V6 is located in a region where the second electrode plate Ce2 is located, an orthographic projection of the sixth via hole V6 on the base substrate 110 is within a range of an orthographic projection of the second electrode plate Ce2 on the base substrate 110, the sixth insulating layer, the fifth insulating layer and the fourth insulating layer in the sixth via hole V6 are etched away, and the surface of the second electrode plate Ce2 is exposed. The sixth via hole V6 is configured such that the subsequently formed fifth connection electrode 45 is connected with the second electrode plate Ce2 through the sixth via hole V6.

The seventh via hole V7 exposes a surface of a first region of the first active layer. The seventh via hole V7 is configured such that the first electrode of the subsequently formed first transistor T1 is connected with the first active layer through the seventh via hole V7. The eighth via hole V8 exposes a surface of a first region of the seventh active layer. The eighth via hole V8 is configured such that the subsequently formed first initial signal line is connected with the seventh active layer through the eighth via hole V8. The ninth via hole V9 exposes a surface of a second region of the sixth active layer. The ninth via hole V9 is configured such that a second electrode of the subsequently formed sixth transistor T6 is connected with the sixth active layer through the ninth via hole V9, and a second electrode of the subsequently formed seventh transistor T7 is connected with the seventh active layer through the ninth via hole V9.

The tenth via hole V10 exposes a surface of a first region of the fourth active layer. The tenth via hole V10 is configured such that the subsequently formed second connection electrode 42 is connected with the fourth active layer through the tenth via hole V10. The eleventh via hole V11 exposes a surface of the second initial signal line INIT2. The eleventh via hole V11 is configured such that the subsequently formed sixth connection electrode 46 is connected with the second initial signal line INIT2 through the eleventh via hole V11.

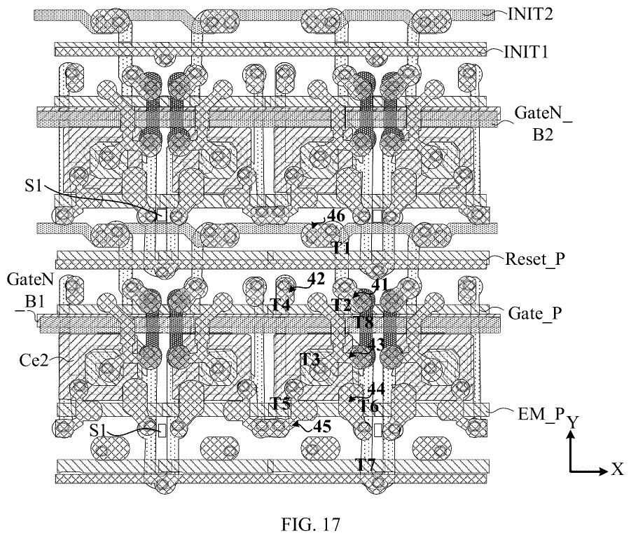

FIG. 17 illustrates a schematic plan view of the fourth conductive layer stacked after the third conductive layer. As shown in FIG. 17, the fourth conductive layer includes: a first initial signal line INIT1, a first connection electrode 41, a second connection electrode 42, a third connection electrode 43, a fourth connection electrode 44, a fifth connection electrode 45 and a sixth connection electrode 46. In some embodiments, the fourth conductive layer may be referred to as a first source/drain metal (SD1) layer.

In some embodiments, in the second direction Y, the fourth conductive layer of any two adjacent columns of sub-pixels is a mirror-symmetrical structure.

In some embodiments, the first initial signal line INIT1 extends along the first direction X, the first initial signal line INIT1 is connected to a first region of the seventh active layer through the eighth via hole V8, so that a first electrode of the seventh transistor T7 has the same electrical potential as the first initial signal line INIT1.

In some embodiments, one end of the first connection electrode 41 is connected with a first region of the second active layer (which is also a second region of the first active layer) through the third via hole V3, and another end of the first connection electrode 41 is connected with a first region of the eighth active layer through the second via hole V2. In some embodiments, the first connection electrode 41 may serve as a first electrode of the eighth transistor T8, a first electrode of the second transistor and a second electrode of the first transistor.

In some embodiments, on one hand, the second connection electrode 42 is connected to the first region of the fourth active layer through the tenth via hole V10, on the other hand, the second connection electrode 42 is connected with a subsequently formed data signal line Data through a subsequently formed thirteenth via hole V13. In some embodiments, the second connection electrode 42 may serve as a first electrode of the fourth transistor T4.

In some embodiments, one end of the third connection electrode 43 is connected with a second region of the eighth active layer through the first via hole V1, and another end of the third connection electrode 43 is connected with the first electrode plate Ce1 through the fourth via hole V4. In some embodiments, the third connection electrode 43 may serve as a second electrode of the eighth transistor T8.

In some embodiments, on one hand, the fourth connection electrode 44 is connected to a second region of the sixth active layer (which is also a second region of the seventh active layer) through the ninth via hole V9, on the other hand, the fourth connection electrode 44 is connected with the subsequently formed first electrode connection electrode through a subsequently formed twelfth via hole V12. In some embodiments, the fourth connection electrode 44 may serve as both the second electrode of the sixth transistor T6 and the second electrode of the seventh transistor T7.

In some embodiments, on one hand, the fifth connection electrode 45 (power supply connection electrode) is connected with the second electrode plate Ce2 through the sixth via hole V6, on the other hand, the fifth connection electrode 45 is connected with a first region of the fifth active layer through the fifth via hole V5, and the fifth connection electrode 45 is configured to be connected with a subsequently formed first power line VDD through a subsequently formed fourteenth via hole V14.

In some embodiments, one end of the sixth connection electrode 46 is connected with the first region of the first active layer through the seventh via hole V7, and another end of the sixth connection electrode 46 is connected with the second initial signal line through the eleventh via hole V11, so that the first electrode of the first transistor T1 has the same electrical potential as the second initial signal line INIT2.

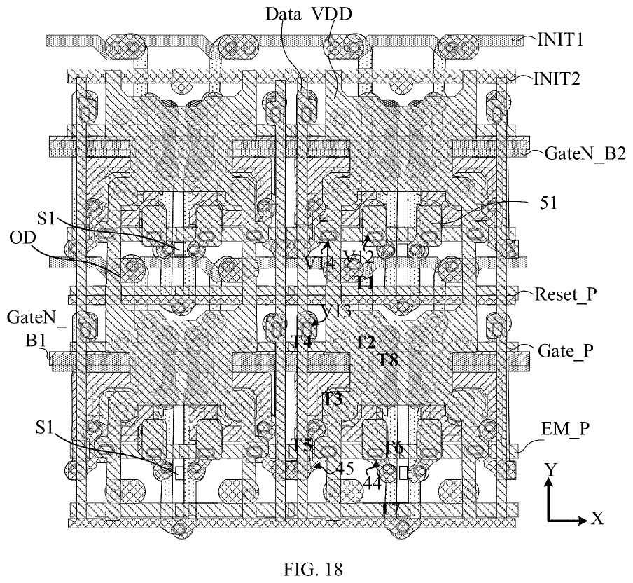

FIG. 18 illustrates a schematic plan view of a first planarization layer stacked after the fourth conductive layer and a fifth conductive layer stacked after the first planarization layer. In some embodiments, as shown in FIG. 18, the first planarization layer 97 includes: a twelfth via hole V12, a thirteenth via hole V13 and a fourteenth via hole V14, and the fifth conductive layer includes: a data signal line Data, a first power line VDD and a first electrode connection electrode 51. In some embodiments, the fifth conductive layer may be referred to as a second source/drain metal (SD2) layer.

In some embodiments, in the second direction Y, the fifth conductive layer of any two adjacent columns of sub-pixels is a mirror-symmetrical structure. In some other exemplary embodiments, in the second direction Y, the fifth conductive layer of any two adjacent columns of sub-pixels may not be a mirror-symmetrical structure, an area of the second source/drain metal layer under the second opening or the third opening may be increased as required, so as to increase the flatness of the first electrode (anode) formed on an upper layer, such that the sub-pixels are located on one plane as a whole, thereby reducing color cast and improving the display quality.

In some embodiments, as shown in FIG. 18, within a repeating unit, the first power supply lines VDD in two adjacent columns of sub-pixels may be an integral structure connected with each other. By forming the first power supply lines VDD in two adjacent columns of sub-pixels as an integral structure connected to each other, the anode formed in the upper layer can be more flat.

For example, the driving circuit layer includes third signal lines (such as the above-mentioned first power lines VDD) disposed parallel with each other and periodically arranged, the third signal lines extend along the second direction Y, and intersect the first signal lines and the second signal lines respectively, the third signal lines are configured to provide power supply signals to the plurality of sub-pixels, as shown in FIG. 18, the third signal lines includes hollow parts OD, the orthographic projections of the first light transmission openings (third openings) S1 on the base substrate 110 are located within the orthographic projections of the hollow parts OD on the base substrate 110. Accordingly, the orthographic projections of the third light transmission openings (second openings) BM2 on the base substrate 110 are located within the orthographic projections of the hollow parts OD1 on the base substrate 110.

In some embodiments, the first electrode connection electrode 51 may be in the shape of a rectangle, and the first electrode connection electrode 51 is connected with the fourth connection electrode 44 through the twelfth via hole V12.

In some embodiments, the first power line VDD is connected with the fifth connection electrode 45 through the fourteenth via hole V14.

In some embodiments, the data signal line Data extends along the second direction Y, the data signal line Data is connected with the second connection electrode 42 through the thirteenth via hole V13, since the second connection electrode 42 is connected with the first region of the fourth active layer through the tenth via hole V10, the connection of the data signal line to the first electrode of the fourth transistor is achieved, so that the data signal transmitted by the data signal line Data can be written into the fourth transistor.

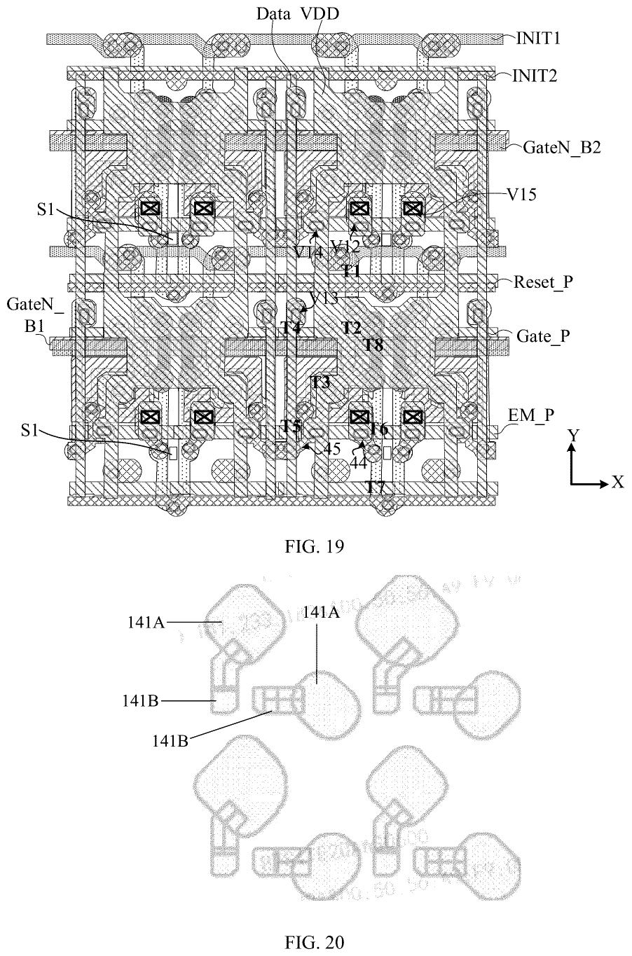

For example, FIG. 19 illustrates a schematic plan view of the second planarization layer stack after the fifth conductive layer. In some embodiments, as shown in FIG. 19, the second planar layer 98 includes a fifteenth via hole V15.

In some embodiments, the fifteenth via hole V15 is located in a region where the first electrode connection electrode 51 is located, the second flat layer in the fifteenth via hole V15 is removed to expose a surface of the first electrode connection electrode 51, and the fifteenth via hole V15 is configured to connect a subsequently formed first electrode (e.g., an anode) with the first electrode connection electrode 51 through the fifteenth via hole V15.

For example, for clarity, FIG. 20 illustrates a schematic plan view of the first electrode layer. As shown in FIG. 20, the first electrode layer includes first electrodes 141 of the plurality of sub-pixels, each of the first electrodes 141 includes a body part 141A and a connection part 141B, the body part 141A is exposed by the sub-pixel opening 130, and the connection part 141B is connected with the first electrode connection electrode 51 through the fifteenth via hole V15.

Since the first electrode connection electrode 51 is connected with the fourth connection electrode 44 through the twelfth via hole V12, the fourth connection electrode 44 is further connected with the sixth active layer through the ninth via hole V9, thus the pixel driving circuit can drive the light-emitting device to emit light.

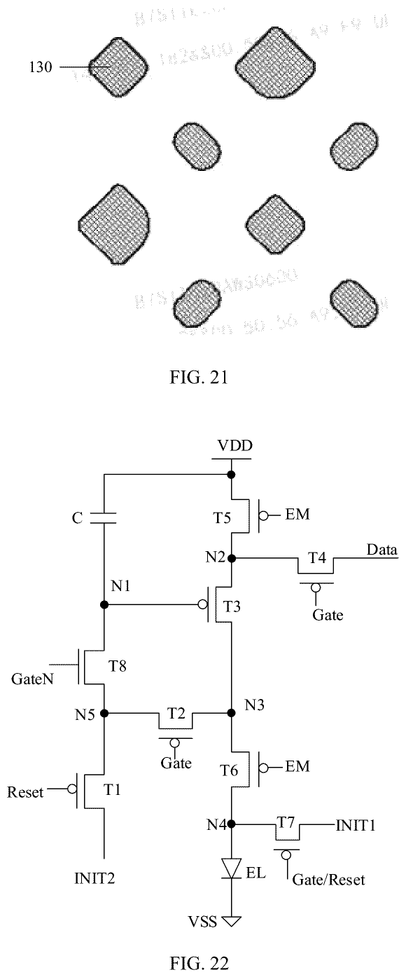

For example, FIG. 21 illustrates a schematic plan view of a pixel definition layer PDL, as shown in FIG. 21, the pixel definition layer PDL includes a plurality of sub-pixel openings 130, the shapes of the plurality of sub-pixel openings 130 are substantially the same as shapes of the body parts 141A of the first electrode 141, and the sizes of the plurality of sub-pixel openings 130 are slightly smaller than the sizes of the body parts 141A, such that the body part 141A are fully exposed.

For example, the structures and positional relationships of the spacer layer 140, the touch layer FM, the black matrix layer BM and the color filter above the pixel definition layer PDL can be referred to FIG. 4, FIG. 6, FIG. 8 and FIG. 9, which will not be repeated herein.

In the embodiments of the present disclosure, the base substrate 110 may be a flexible substrate, or may be a rigid substrate. The rigid substrate may be but not limited to one or more of glass and quartz, and the flexible substrate may be, but not limited to, one or more of polyethylene terephthalate, ethylene terephthalate, polyether ether ketone, polystyrene, polycarbonate, polyarylate, polyarylate, polyimide, polyvinyl chloride, polyethylene and textile fibers. In some embodiments, the flexible substrate may include a first flexible material layer, a first inorganic material layer, a semiconductor layer, a second flexible material layer, and a second inorganic material layer that are stacked, materials of the first flexible material layer and the second flexible material layer may use polyimide (PI), polyethylene terephthalate (PET) or surface-treated polymer soft film, materials of the first inorganic material layer and the second inorganic material layer may use silicon nitride (SiNx), silicon oxide (SiOx), or the like, which is used to improve water and oxygen resistance of the substrate, and the material of the semiconductor layer may use amorphous silicon (a-si).

For example, the first conductive layer, the second conductive layer, the third conductive layer, the fourth conductive layer and the fifth conductive layer may use metal materials, such as any one or more of silver (Ag), copper (Cu), aluminum (Al), titanium (Ti) and molybdenum (Mo), or alloy materials of the above metals, such as aluminum neodymium alloy (AlNd) or molybdenum niobium alloy (MoNb), and may be a single-layer structure, or a multi-layer composite structure, such as Mo/Cu/Mo. The insulating layer may use any one or more of silicon oxide (SiOx), silicon nitride (SiNx) and silicon oxynitride (SiON), and may be single-layer, multi-layer or composite layer. The planarization layer may be made of an organic material, and the plurality of touch lines TL of the touch layer FM may be made of metal oxide materials such as indium tin oxide (ITO) or indium zinc oxide (IZO). The first semiconductor layer may use polysilicon (p-Si), and the second semiconductor layer (SML₂) may use oxide.

The stacked structures of the display substrate provided by the embodiments of the present disclosure are only exemplary illustration. In some embodiments, the corresponding structures can be changed and the patterning processes can be increased or decreased according to actual needs, which are not limited by the embodiments of the present disclosure.

The following statements should be noted:
the accompanying drawings involve only the structure(s) in connection with the embodiment(s) of the present disclosure, and other structure(s) can be referred to common design(s).

For the sake of clarity, in the drawings used to describe the embodiments disclosed herein, the thicknesses of the layers or regions are enlarged or scaled down, that is, these drawings are not drawn to actual scale. It should be understood that if an element such as a layer, a film, a region, or a substrate is described as being located “on” or “below” another element, the element may be “directly” located “on” or “below” the another element, or there may exist an intermediate element.

In case of no conflict, features in one embodiment or in different embodiments can be combined to obtain new embodiments.

What have been described above are only specific implementations of the present disclosure, the protection scope of the present disclosure is not limited thereto, and the protection scope of the present disclosure should be based on the protection scope of the claims.

1: A display substrate, having a plurality of sub-pixels, and comprising:
a base substrate;
a light-shielding layer, disposed on the base substrate, and comprising a plurality of first light transmission openings,
a pixel driving circuit layer, disposed on a side of the light-shielding layer away from the base substrate, and
a pixel definition layer, disposed on a side of the pixel driving circuit layer away from the base substrate, and comprising a plurality of sub-pixel openings,
wherein each of the plurality of sub-pixels comprises a pixel driving circuit disposed in the pixel driving circuit layer and a light-emitting device at least partially disposed in one of the plurality of sub-pixel openings, and
orthographic projections of the plurality of first light transmission openings on the base substrate are respectively located between orthographic projections of adjacent sub-pixel openings of the plurality of sub-pixel openings on the base substrate.

2: The display substrate according to claim 1, further comprising a black matrix layer disposed on a side of the light-emitting device away from the base substrate, wherein the black matrix layer comprises a plurality of second light transmission openings and a plurality of third light transmission openings,
orthographic projections of the plurality of sub-pixel openings on the base substrate are respectively at least partially overlapped with orthographic projections of the plurality of second light transmission openings on the base substrate;
the plurality of third light transmission openings are respectively disposed between adjacent second light transmission openings of the plurality of second light transmission openings; and
orthographic projections of at least part of the plurality of first light transmission openings on the base substrate are respectively at least partially overlapped with orthographic projections of the plurality of third light transmission openings on the base substrate.

3: The display substrate according to claim 2, wherein the orthographic projections of the at least part of the plurality of first light transmission openings on the base substrate are respectively located within the orthographic projections of the plurality of third light transmission openings on the base substrate.

4. (canceled)

5: The display substrate according to claim 2, wherein the pixel driving circuit layer comprises first signal lines and second signal lines disposed parallel to each other and periodically arranged, the first signal lines and the second signal lines are configured to provide different electrical signals to the plurality of sub-pixels,
the orthographic projections of the plurality of first light transmission openings on the base substrate are respectively located between an orthographic projection of one of the first signal lines on the base substrate and an orthographic projection of one of the second signal lines closest to the one of the first signal lines on the base substrate.

6-7. (canceled)

8: The display substrate according to claim 5, wherein the driving circuit layer comprises third signal lines disposed in parallel and arranged periodically, the third signal lines intersect the first signal lines and the second signal lines respectively, the third signal lines are configured to provide power supply signals to the plurality of sub-pixels, and the third signal lines comprise hollow parts, and
the orthographic projections of the first light transmission openings on the base substrate are located within orthographic projections of the hollow parts on the base substrate.

9: The display substrate according to claim 8, wherein orthographic projections of the third light transmission openings on the base substrate are not overlapped with orthographic projections of the first signal lines and orthographic projections of the second signal lines on the base substrate, and
the orthographic projections of the third light transmission openings on the base substrate are located within the orthographic projections of the hollow parts on the base substrate.

10: The display substrate according to claim 2, wherein the plurality of sub-pixels comprise first sub-pixels, second sub-pixels and third sub-pixels,
the black matrix layer further comprises a plurality of color filters at least partially disposed in the plurality of second light transmission openings,
the plurality of color filters comprise first color filters, second color filters and third color filters,
orthographic projections of sub-pixel openings of the first sub-pixels on the base substrate are located within orthographic projections of the first color filters on the base substrate,
orthographic projections of sub-pixel openings of the second sub-pixels on the base substrate are located within orthographic projections of the second color filters on the base substrate, and
orthographic projections of sub-pixel openings of the third sub-pixels on the base substrate are located within orthographic projections of the third color filters on the base substrate.

11: The display substrate according to claim 10, wherein at least part of the plurality of third light transmission openings is located between second light transmission openings corresponding to the first sub-pixel and the third sub-pixel adjacent to each other, and a minimum distance between the at least part of the plurality of third light transmission openings and the second light transmission opening corresponding to the first sub-pixel is a first distance, a minimum distance between the at least part of the plurality of third light transmission openings and the second light transmission opening corresponding to the third sub-pixel is a second distance, and
the first distance is different from the second distance.

12: The display substrate according to claim 11, wherein the first sub-pixels and the third sub-pixels are disposed in multiple rows and multiple columns,
a plurality of first sub-pixels and a plurality of third sub-pixels in a same column are disposed alternately, and one third light transmission opening is disposed between the second light transmission openings corresponding to the first sub-pixel and the third sub-pixel adjacent to each other in the same column.

13: The display substrate according to claim 12, wherein the second distance between the one third light transmission opening and the second light transmission opening corresponding to the third sub-pixel is smaller than the first distance between the one third light transmission opening and the second light transmission opening corresponding to the first sub-pixel.

14: The display substrate according to claim 13, wherein for the sub-pixel opening and the third color filter corresponding to the third sub-pixel,
an orthographic projection of the sub-pixel opening on the base substrate is located within an orthographic projection of the third color filter on the base substrate, a distance between a boundary of the orthographic projection of the sub-pixel opening on the base substrate and a boundary of the orthographic projection of the third color filter on the base substrate at a side close to the one third light transmission opening is smaller than a distance between the boundary of the orthographic projection of the sub-pixel opening on the base substrate and the boundary of the orthographic projection of the third color filter on the base substrate at a side away from the one third light transmission opening.

15: The display substrate according to claim 14, wherein for the sub-pixel opening and the second light transmission opening corresponding to the third sub-pixel,
the orthographic projection of the sub-pixel opening on the base substrate is located within an orthographic projection of the second light transmission opening on the base substrate, and a distance between the boundary of the orthographic projection of the sub-pixel opening on the base substrate and a boundary of the orthographic projection of the second light transmission opening on the base substrate at a side close to the one third light transmission opening is smaller than a distance between the boundary of the orthographic projection of the sub-pixel opening on the base substrate and the boundary of the orthographic projection of the second light transmission opening on the base substrate at a side away from the one third light transmission opening.

16: The display substrate according to claim 14, wherein for the sub-pixel opening and the first color filter corresponding to the first sub-pixel,
the orthographic projection of the sub-pixel opening on the base substrate is located within an orthographic projection of the first color filter on the base substrate, and a distance between the boundary of the orthographic projection of the sub-pixel opening on the base substrate and a boundary of the orthographic projection of the first color filter on the base substrate at a side close to the one third light transmission opening is substantially equal to a distance between the boundary of the orthographic projection of the sub-pixel opening on the base substrate and the boundary of the orthographic projection of the first color filter on the base substrate at the side away from the one third light transmission opening.

17: The display substrate according to claim 12, wherein one first sub-pixel, two second sub-pixels and one third sub-pixel constitute one repeating unit, and a plurality of repeating units are disposed in an array,
a plurality of second sub-pixels in the plurality of repeating units are arranged in multiple rows and multiple columns, and the one third light transmission opening is further disposed between second light transmission openings corresponding to adjacent second sub-pixels in a row direction.

18. (canceled)

19: The display substrate according to claim 17, wherein each of the plurality of repeating units is correspondingly disposed with two first light transmission openings and two third light transmission openings; and orthographic projections of the two first light transmission openings on the base substrate are respectively located within orthographic projections of the two third light transmission openings on the base substrate; or
wherein each of the plurality of repeating units is correspondingly disposed with two first light transmission openings, and each of the plurality of repeating units or every plurality of repeating units is correspondingly disposed with one third light transmission opening, orthographic projections of a part of the plurality of first light transmission openings on the base substrate are respectively within orthographic projections of the plurality of third light transmission openings on the base substrate.

20-23. (canceled)

24: The display substrate according to claim 10, further comprising an encapsulation layer disposed on a side of the light-emitting device away from the base substrate and a touch layer disposed on a side of the encapsulation layer away from the base substrate,
the black matrix layer is disposed on a side of the encapsulation layer away from the base substrate; the black matrix layer is disposed on a side of the touch layer away from the base substrate, the touch layer comprises a plurality of touch lines, and
orthographic projections of the plurality of touch lines on the base substrate do not overlap with orthographic projections of the plurality of first light transmission openings on the base substrate.

25-28. (canceled)

29: A display device, comprising:
the display substrate according to claim 1, and
a sensor, disposed on a side of the base substrate of the display substrate away from the light-shielding layer,
wherein in a direction perpendicular to the base substrate, the sensor is overlapped with at least one of the plurality of first light transmission openings.

30: A display substrate, having a plurality of sub-pixels, wherein the plurality of sub-pixels comprise first sub-pixels, second sub-pixels, and third sub-pixels; the first sub-pixels and the third sub-pixels are disposed alternately along a row direction to form a plurality of first pixel rows, and the first sub-pixels and the third sub-pixels in a same column among the plurality of first pixel rows are disposed alternately, the second sub-pixels are disposed side by side along the row direction to form a plurality of second pixel rows; and the display substrate comprises:
a base substrate,
a pixel driving circuit layer, disposed on the base substrate,
a pixel definition layer, disposed on a side of the pixel driving circuit layer away from the base substrate, and comprising a plurality of sub-pixel openings, wherein each of the plurality of sub-pixels comprises a pixel driving circuit disposed in the pixel driving circuit layer and a light-emitting device at least partially disposed in one of the plurality of sub-pixel openings, and
a black matrix layer, comprising a plurality of first openings and a plurality of second openings, wherein orthographic projections of the plurality of sub-pixel openings on the base substrate are respectively at least partially overlapped with orthographic projections of the plurality of first openings on the base substrate, so that light emitted by light-emitting devices of the plurality of sub-pixels can exit through the plurality of first openings; and the plurality of second openings are respectively disposed between the first openings corresponding to the first sub-pixels and the third sub-pixels adjacent in the column direction.

31-34. (canceled)

35: The display substrate according to claim 30, wherein for one of the plurality of second openings and first openings corresponding to the first sub-pixel and the third sub-pixel adjacent to the one of the plurality of second openings,
a line connecting centers of the first openings corresponding to the first sub-pixel and the third sub-pixel that are adjacent to the one of the plurality of second openings passes through the one of the plurality of second openings.

36. (canceled)

37: The display substrate according to claim 30, wherein the plurality of second openings are respectively disposed between first openings corresponding to adjacent second sub-pixels in the row direction.

38-46. (canceled)
